(19) United States
(12) Patent Application Publication
(10) Pub. No.: US 2015/0146489 A1
(43) Pub. Date: May 28, 2015

(54) METHOD OF OPERATING NONVOLATILE MEMORY DEVICE

(71) Applicants: Chang-Hyun LEE, Suwon-si (KR); Albert FAYRUSHIN, Suwon-si (KR)

(72) Inventors: Chang-Hyun LEE, Suwon-si (KR); Albert FAYRUSHIN, Suwon-si (KR)

(21) Appl. No.: 14/477,513

(22) Filed: Sep. 4, 2014

(30) Foreign Application Priority Data
Nov. 26, 2013 (KR) 10-2013-0144231

(51) Int. Cl. G11C 16/14; G11C 16/34

(52) U.S. Cl. CPC G11C 16/14; G11C 16/3459
USPC 365/185.22; 365/185.29; 365/185.18

(57) ABSTRACT

In a method of operating a nonvolatile memory device having a substrate and first through n-th word lines stacked in a direction perpendicular to the substrate, first through k-th word line voltages are applied to first through k-th word lines, respectively, which are formed adjacent to the substrate, among the first through n-th word lines. (k+1)-th through n-th word line voltages are applied to (k+1)-th through n-th word lines, respectively, which are formed above the first through k-th word lines, among the first through n-th word lines. An erase voltage, which is higher than the first through n-th word line voltages, is applied to the substrate, where n represents an integer equal to or greater than two, and k represents a positive integer smaller than n. Each of the (k+1)-th through n-th word line voltages is lower than each of the first through k-th word line voltages.

### CROSS-REFERENCE TO RELATED APPLICATION

This application claims under 35 USC §119 priority to and the benefit of Korean Patent Application No. 10-2013-0144231, filed on Nov. 26, 2013 in the Korean Intellectual Property Office (KIPO), the entire contents of which are incorporated by reference herein.

### BACKGROUND

1. Technical Field

The present disclosure relates to a nonvolatile memory device, and, more particularly, to a method of erasing a nonvolatile memory device and a method of programming a nonvolatile memory device.

2. Description of the Related Art

Memory devices can be broadly classified into two groups based upon whether they retain stored data when disconnected from power. These groups include volatile memory devices, which lose stored data when disconnected from power, and nonvolatile memory devices, which retain stored data when disconnected from power.

Examples of volatile memory devices include dynamic random access memory (DRAM), and static random access memory (SRAM). Examples of nonvolatile memory devices include electrically erasable and programmable read only memory (EEPROM), phase-change random access memory (PRAM), resistance random access memory (RRAM), and magnetic random access memory (MRAM).

EEPROM is one of the more common forms of nonvolatile memory in use today due to its ability to be efficiently programmed, read, and erased. Flash EEPROM (hereafter, “flash memory”), for instance, can be found in a wide range of modern electronic devices, including solid state drives, mobile phones, digital cameras, and many others.

Flash memory devices have different operating modes for performing program, read, and erase operations. These modes will be referred to as a program mode, a read-out mode, and an erase mode.

Flash memory devices store data in a memory cell by changing a threshold voltage of the memory cell. The memory cell included in flash memory devices has one of a threshold voltage distribution of an erased state and a threshold voltage distribution of a programmed state based upon data stored in the memory cell. Flash memory devices can read out data stored in the memory cell based upon the threshold voltage distribution of the memory cell. To ensure accurate read operations, the threshold voltage distributions must be separated from each other by an adequate read margin. If the threshold voltage distributions overlap each other or are too close together, memory cells belonging to one distribution can be erroneously read as belonging to the other distribution.

### SUMMARY

Exemplary embodiments of the present inventive concepts are directed to provide a method of erasing a nonvolatile memory device capable of narrowing a threshold voltage distribution of a memory cell.

Exemplary embodiments are also directed to provide a method of programming a nonvolatile memory device capable of increasing the program speed.

In a method of operating a nonvolatile memory device having a substrate and first through n-th word lines stacked in a direction perpendicular to the substrate, first through k-th word line voltages are applied to first through k-th word lines, respectively, which are formed adjacent to the substrate, among the first through n-th word lines. (k+1)-th through n-th word line voltages are applied to (k+1)-th through n-th word lines, respectively, which are formed above the first through k-th word lines, among the first through n-th word lines. An erase voltage, which is higher than the first through n-th word line voltages, is applied to the substrate. Each of the (k+1)-th through n-th word line voltages is lower than each of the first through k-th word line voltages. Here, n represents an integer equal to or greater than two, and k represents a positive integer smaller than n.

In exemplary embodiments, the first through k-th word line voltages may be positive voltages and the (k+1)-th through n-th word line voltages may be ground voltages.

I-th word line voltage may be equal to or higher than j-th word line voltage, where i and j are positive integers equal to or smaller than k and j is greater than i.

In exemplary embodiments, the first through k-th word line voltages may be ground voltages and the (k+1)-th through n-th word line voltages may be negative voltages.

In exemplary embodiments, i-th word line voltage may be equal to or higher than j-th word line voltage, where i and j are positive integers equal to or smaller than n and j is greater than i.

In exemplary embodiments, the first through n-th word lines may be connected to gate electrodes of first through n-th memory cells, respectively, and an m-th word line voltage may be higher than the rest of the first through k-th word line voltages when the m-th memory cell has an a typical shape, where m is a positive integer equal to or smaller than k.

In exemplary embodiments, the first through n-th word line voltages may be provided from a voltage generation unit included in the nonvolatile memory device.

In a method of operating a nonvolatile memory device having a substrate and first through n-th word lines stacked in a direction perpendicular to the substrate, a ground voltage is applied to the first through n-th word lines, an erase voltage is applied to the substrate, and first through k-th word lines, which are formed adjacent to the substrate, among the first through n-th word lines are floated. Here, n represents an integer equal to or greater than two, and k represents a positive integer equal to or smaller than n.

In exemplary embodiments, floating the first through k-th word lines may include floating the first through k-th word lines when a reference time elapses from a time at which the erase voltage is applied to the substrate.

The nonvolatile memory device may further include a timer, and whether the reference time elapses from the time at which the erase voltage may be applied to the substrate is determined using the timer.

In exemplary embodiments, floating the first through k-th word lines may include floating the first through k-th word lines when a voltage of the substrate reaches a reference voltage.

The nonvolatile memory device may further include a voltage detection unit configured to detect the voltage of the substrate, and whether the voltage of the substrate reaches the reference voltage may be determined using the voltage detection unit.

In exemplary embodiments, floating the first through k-th word lines may include floating the first through k-th word lines one by one in an order from the first word line to the k-th word line after the erase voltage is applied to the substrate.

Floating the first through k-th word lines one by one in an order from the first word line to the k-th word line after the erase voltage is applied to the substrate may include floating the first through k-th word lines when first through k-th reference times elapse, respectively, from a time at which the erase voltage is applied to the substrate, where i-th reference time is smaller than j-th reference time. Here, i and j are positive integers equal to or smaller than k and j is greater than i.

Floating the first through k-th word lines one by one in an order from the first word line to the k-th word line after the erase voltage is applied to the substrate may include floating the first through k-th word lines when a voltage of the substrate reaches first through k-th reference voltages, respectively, where i-th reference voltage is smaller than j-th reference voltage. Here, i and j are positive integers equal to or smaller than k and j is greater than i.

In exemplary embodiments, applying the ground voltage to the first through n-th word lines may include applying the ground voltage to first through n-th pass transistors, which are coupled to the first through n-th word lines, respectively, and turning on the first through n-th pass transistors. Floating the first through k-th word lines may include turning off first through k-th pass transistors, which are coupled to the first through k-th word lines, respectively, after the erase voltage is applied to the substrate.

Turning off the first through k-th pass transistors after the erase voltage is applied to the substrate may include turning off the first through k-th pass transistors one by one in an order from the first pass transistor to the k-th pass transistor after the erase voltage is applied to the substrate.

In a method of operating a nonvolatile memory device including a substrate and first through n-th word lines stacked in a direction perpendicular to the substrate, a target memory cell connected to i-th word line may be programmed by applying a first program voltage to the i-th word line, where a level of the first program voltage increases in steps from a first voltage as program loops are repeated, and a target memory cell connected to j-th word line, which is formed above the i-th word line, may be programmed by applying a second program voltage to the j-th word line, where a level of the second program voltage increases in steps from a second voltage, which is higher than the first voltage, as program loops are repeated. Here, i represents a positive integer equal to or smaller than n, and j represents an integer greater than i and equal to or smaller than n.

In exemplary embodiments, a stepwise increment of the first program voltage may be substantially the same as a stepwise increment of the second program voltage.

In exemplary embodiments, the method of operating the nonvolatile memory device may further include verifying whether the target memory cell connected to the i-th word line is in a programmed state by applying a verification voltage having a constant magnitude to the i-th word line in each program loop while programming the target memory cell connected to the i-th word line, and verifying whether the target memory cell connected to the j-th word line is in a programmed state by applying the verification voltage having the constant magnitude to the j-th word line in each program loop while programming the target memory cell connected to the j-th word line.

### BRIEF DESCRIPTION OF THE DRAWINGS

Illustrative, non-limiting exemplary embodiments will be more clearly understood from the following detailed description in conjunction with the accompanying drawings.

FIG. 1 is a block diagram illustrating a nonvolatile memory device according to exemplary embodiments.

FIG. 2 is a plane diagram illustrating a memory block included in the nonvolatile memory device of FIG. 1 according to an exemplary embodiment of the present inventive concept.

FIG. 3 is a perspective view of the memory block of FIG. 2 taken along the line I-I′ in FIG. 2 according to an exemplary embodiment of the present inventive concept.

FIG. 4 is a cross-sectional view of the memory block of FIG. 2 taken along the line I-I′ in FIG. 2 according to an exemplary embodiment of the present inventive concept.

FIG. 5 is a diagram illustrating one of cell transistors included in a memory block of FIGS. 2, 3 and 4 according to an exemplary embodiment of the present inventive concept.

FIG. 6 is a circuit diagram illustrating an equivalent circuit of a memory block of FIGS. 2, 3 and 4 according to an exemplary embodiment of the present inventive concept.

FIG. 7 is a diagram illustrating a plane structure of an equivalent circuit diagram of FIG. 6 according to an exemplary embodiment of the present inventive concept.

FIG. 8 is a flow chart illustrating a method of erasing a nonvolatile memory device according to exemplary embodiments.

FIG. 9 is a circuit diagram for describing the method of erasing the nonvolatile memory device of FIG. 8 according to an exemplary embodiment of the present inventive concept.

FIG. 10 is a circuit diagram for describing the method of erasing the nonvolatile memory device of FIG. 8 according to an exemplary embodiment of the present inventive concept.

FIG. 11 is a circuit diagram for describing the method of erasing the nonvolatile memory device of FIG. 8 according to an exemplary embodiment of the present inventive concept.

FIG. 12 is a circuit diagram for describing the method of erasing the nonvolatile memory device of FIG. 8 according to an exemplary embodiment of the present inventive concept.

FIG. 13 is a flow chart illustrating a method of erasing a nonvolatile memory device according to exemplary embodiments.

FIG. 14 is a circuit diagram illustrating a word line connection between the address decoder and the memory cell array of FIG. 1 according to an exemplary embodiment of the present inventive concept.

FIG. 15 is a graph for describing the method of erasing the nonvolatile memory device of FIG. 13 according to an exemplary embodiment of the present inventive concept.

FIG. 16 is a graph for describing the method of erasing the nonvolatile memory device of FIG. 13 according to an exemplary embodiment of the present inventive concept.

FIG. 17 is a block diagram illustrating the nonvolatile memory device of FIG. 1 according to an exemplary embodiment of the present inventive concept.

FIG. 18 is a block diagram illustrating the nonvolatile memory device of FIG. 1 according to an exemplary embodiment of the present inventive concept.

FIG. 19 is a flow chart illustrating a method of programming a nonvolatile memory device according to exemplary embodiments.

FIGS. 20A and 20B are graphs for describing the method of programming the nonvolatile memory device of FIG. 19 according to an exemplary embodiment of the present inventive concept.

FIG. 21 is a block diagram illustrating a memory system according to exemplary embodiments.

FIG. 22 is a block diagram illustrating a memory card according to exemplary embodiments.

FIG. 23 is a block diagram illustrating a solid state drive (SSD) system according to exemplary embodiments.

FIG. 24 is a block diagram illustrating a mobile system according to exemplary embodiments.

### DETAILED DESCRIPTION OF THE EMBODIMENTS

Various exemplary embodiments will be described more fully with reference to the accompanying drawings, in which some exemplary embodiments are shown. The present inventive concept may, however, be embodied in many different forms and should not be construed as limited to the embodiments set forth herein. Rather, these embodiments are provided so that this disclosure will be thorough and complete, and will fully convey the scope of the present inventive concept to those skilled in the art. Like reference numerals refer to like elements throughout this application.

It will be understood that, although the terms first, second, etc. may be used herein to describe various elements, these elements should not be limited by these terms. These terms are used to distinguish one element from another. For example, a first element could be termed a second element, and, similarly, a second element could be termed a first element, without departing from the scope of the present inventive concept. As used herein, the term “and/or” includes any and all combinations of one or more of the associated listed items.

It will be understood that when an element is referred to as being “connected” or “coupled” to another element, it can be directly connected or coupled to the other element or intervening elements may be present. Other words used to describe the relationship between elements should be interpreted in a like fashion (e.g., “between” versus “directly between,” “adjacent” versus “directly adjacent,” etc.).

The terminology used herein is for the purpose of describing particular embodiments and is not intended to be limiting of the inventive concept. As used herein, the singular forms “a,” “an” and “the” are intended to include the plural forms as well, unless the context clearly indicates otherwise. It will be further understood that the terms “comprises,” “comprising,” “includes” and/or “including,” when used herein, specify the presence of stated features, integers, steps, operations, elements, and/or components, but do not preclude the presence or addition of one or more other features, integers, steps, operations, elements, components, and/or groups thereof.

Unless otherwise defined, all terms (including technical and scientific terms) used herein have the same meaning as commonly understood by one of ordinary skill in the art to which this inventive concept belongs. It will be further understood that terms, such as those defined in commonly used dictionaries, should be interpreted as having a meaning that is consistent with their meaning in the context of the relevant art and will not be interpreted in an idealized or overly formal sense unless expressly so defined herein.

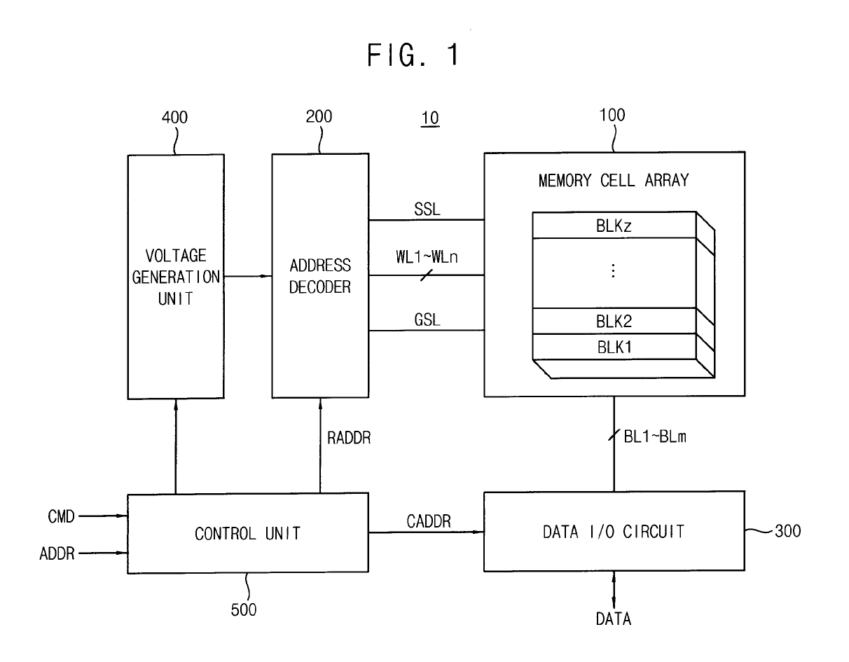

FIG. 1 is a block diagram illustrating a nonvolatile memory device according to the exemplary embodiments.

Referring to FIG. 1, a nonvolatile memory device 10 includes a memory cell array 100, an address decoder 200, a data input/output (I/O) circuit 300, a voltage generation unit 400 and a control unit 500.

The memory cell array 100 is formed on a substrate in a three-dimensional structure. For example, memory cells included in the memory cell array 100 may be formed in a direction perpendicular to the substrate.

The memory cells included in the memory cell array 100 may be connected to a plurality of word lines WL1˜WLn (i.e., WL1, WL2, . . . WLn), which are stacked in a direction perpendicular to the substrate, and a plurality of bit lines BL1˜BLm (i.e., BL1, BL2, . . . BLm), which are formed in a direction parallel to the substrate. Here, n and m represent integers equal to or greater than two. For example, memory cells formed at a same height from the substrate may be connected to a same word line. Memory cells formed in a direction perpendicular to the substrate may form a cell string. A plurality of cell strings may be connected to each of the plurality of bit lines BL1˜BLm.

The memory cell array 100 may include a plurality of memory blocks BLK1, BLK2, . . . , BLKz. Here, z represents a positive integer. Each of the plurality of memory blocks BLK1, BLK2, . . . , BLKz may include a plurality of cell strings. The plurality of memory blocks BLK1, BLK2, . . . , BLKz may share the plurality of bit lines BL1, BL2, . . . BLm. The memory cell array 100 may perform an erase operation by a unit of a memory block.

In some exemplary embodiments, the memory cell included in the memory cell array 100 may be a single-level cell for storing single-bit data.

In other exemplary embodiments, the memory cell included in the memory cell array 100 may be a multi-level cell for storing multi-bit data.

The control unit 500 may the control overall operations of the nonvolatile memory device 10 by controlling the voltage generation unit 400, the address decoder 200 and the data I/O circuit 300 based upon a command signal CMD and an address signal ADDR received from an external device such as a memory controller. For example, the control unit 500 may control a program operation, a read operation, and the erase operation of the nonvolatile memory device 10 based upon the command signal CMD and the address signal ADDR.

In some exemplary embodiments, the control unit 500 may generate a row address RADDR and a column address CADDR based upon the address signal ADDR. The control unit 500 may provide the row address RADDR to the address decoder 200 and provide the column address CADDR to the data I/O circuit 300.

The voltage generation unit 400 generates various voltages required for operations of the nonvolatile memory device 10. For example, the voltage generation unit 400 may generate a program voltage, a pass voltage and a verification voltage that are used in the program operation, generate a read voltage that is used in the read operation, and generate an erase voltage that is used in the erase operation.

The address decoder 200 is connected to the memory cell array 100 through the plurality of word lines WL1˜WLn, at least one string selection line SSL, and at least one ground selection line GSL. The address decoder 200 may select one of the plurality of word lines WL1˜WLn based upon the row address RADDR received from the control unit 500, and provide various voltages received from the voltage generation unit 400 to the selected word line and the unselected word lines.

The data I/O circuit 300 is connected to the memory cell array 100 through the plurality of bit lines BL1˜BLm. The data I/O circuit 300 may select at least one of the plurality of bit lines BL1˜BLm based upon the column address CADDR received from the control unit 500, output data read from a memory cell connected to the selected at least one bit line to an external device, and write data received from the external device in a memory cell connected to the selected at least one bit line.

In some exemplary embodiments, the data I/O circuit 300 may perform a copy-back operation, in which data stored in a first storage area of the memory cell array 100 is copied to a second storage area of the memory cell array 100.

In some exemplary embodiments, the data I/O circuit 300 may include a sense amplifier, a page buffer, a column selection circuit, a write driver, a data buffer, etc.

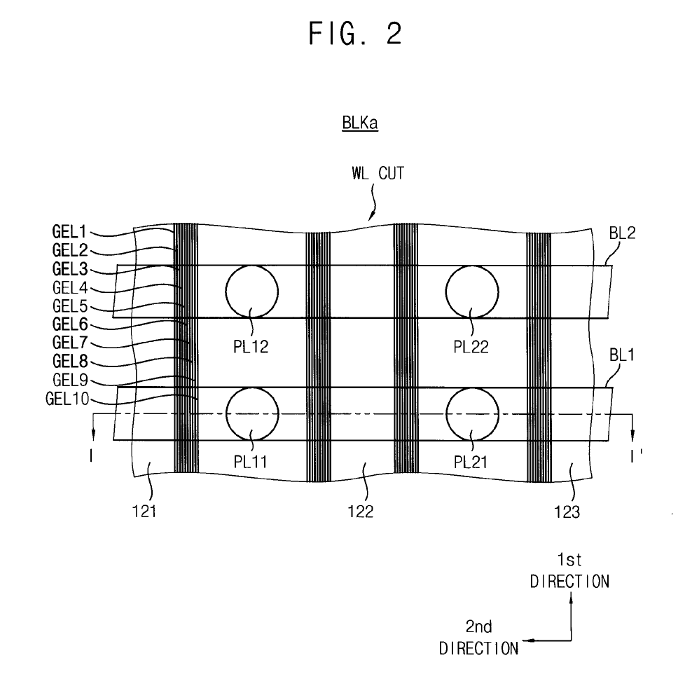

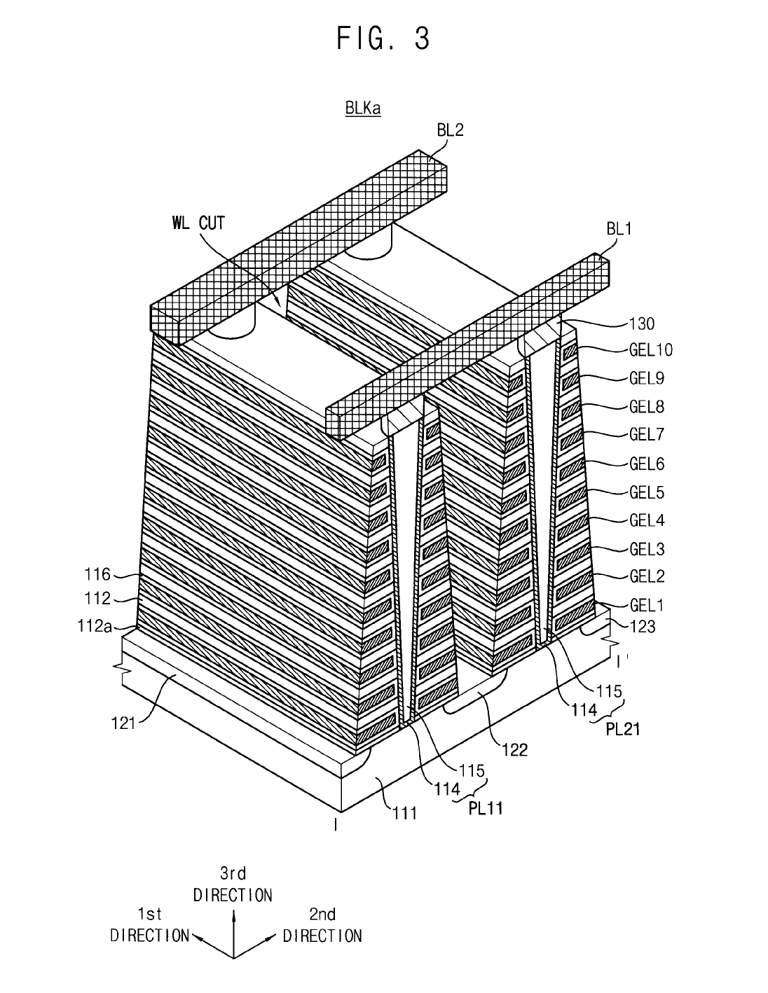

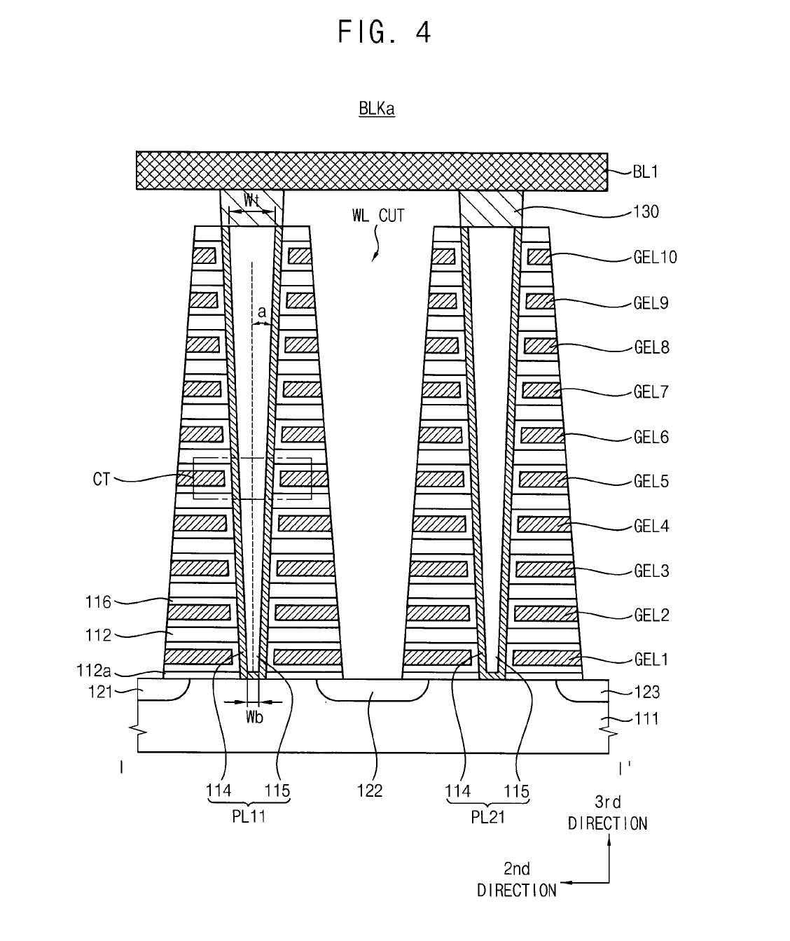

FIG. 2 is a plane diagram illustrating an example of a memory block included in the nonvolatile memory device of FIG. 1. FIG. 3 is a perspective view of the memory block of FIG. 2. FIG. 4 is a cross-sectional view of the memory block of FIG. 2 taken along a line I-I′ in FIG. 2.

FIGS. 2, 3 and 4 represent a part of a memory block BLKa among the plurality of memory blocks BLK1, BLK2, . . . , BLKz included in the memory cell array 100.

Referring to FIGS. 2, 3 and 4, the memory block BLKa may be formed on a substrate 111 along first, second and third directions such that the memory block BLKa has a three-dimensional structure.

The substrate 111 may be a well having a first conductivity type. For example, the substrate 111 may be a p-well in which the Group III element such as boron is injected. In some exemplary embodiments, the substrate 111 may be a pocket p-well which is provided within an n-well. Hereinafter, it is assumed that the substrate 111 is a p-well (or, a pocket p-well). However, exemplary embodiments are not limited thereto.

A plurality of doping regions 121, 122, 123, which extend along the first direction and are spaced apart along the second direction, may be formed in the substrate 111. In FIGS. 2, 3 and 4, a first doping region 121, a second doping region 122 and a third doping region 123 are illustrated as an example.

The plurality of doping regions 121, 122, 123 may have a second conductivity type that is different from the first conductivity type of the substrate 111. For example, the plurality of doping regions 121, 122, 123 may include an n-type conductive material. Hereinafter, it is assumed that the plurality of doping regions 121, 122, 123 are n-type. However, exemplary embodiments are not limited thereto.

As will be described below, the plurality of doping regions 121, 122, 123 may be coupled to a common source line.

Between adjacent doping regions of the plurality of doping regions 121, 122, 123, a plurality of insulation layers 112, 112a may be formed sequentially on the substrate 111 along the third direction, which is a direction perpendicular to the substrate 111. The plurality of insulation layers 112, 112a may be formed to be spaced apart along the third direction. The plurality of insulation layers 112, 112a may extend along the first direction.

In some exemplary embodiments, the plurality of insulation layers 112, 112a may include an insulating material such as silicon oxide.

In some exemplary embodiments, a thickness of the insulation layer 112a contacting with the substrate 111 may be thinner than that of the insulation layers 112.

Between adjacent doping regions of the plurality of doping regions 121, 122, 123 a plurality of pillars PL11, PL12, PL21, PL22, which are arranged sequentially along the first direction and penetrate the plurality of insulation layers 112, 112a along the third direction, may be formed. The plurality of pillars PL11, PL12, PL21, PL22 may contact with the substrate 111 through the plurality of insulation layers 112, 112a.

In some exemplary embodiments, the plurality of pillars PL11, PL12, PL21, PL22 may be formed by vertically patterning the plurality of insulation layers 112, 112a.

In exemplary embodiments, each of the plurality of pillars PL11, PL12, PL21, PL22 may include an inner material 115 and a channel layer 114 surrounding the inner material 115.

The channel layer 114 may include a semiconductor material (e.g., silicon) having the same conductive type as the substrate 111, which is the first conductive type. For example, the channel layer 114 may include a p-type semiconductor material. Hereinafter, it is assumed that the channel layer 114 is p-type. However, exemplary embodiments are not limited thereto. For example, the channel layer 114 may include an intrinsic semiconductor being a nonconductor.

The inner material 115 may include an insulation material. In some exemplary embodiments, the inner material 115 may include silicon oxide. In other exemplary embodiments, the inner material 115 may alternatively be an air gap.

As illustrated in FIGS. 3 and 4, between adjacent doping regions of the plurality of doping regions 121, 122, 123 charge storage layers 116 may be formed along exposed surfaces of the plurality of insulation layers 112, 112a and the channel layers 114. The charge storage layers 116 may store data by trapping charges from the channel layers 114.

As illustrated in FIGS. 3 and 4, a plurality of gate electrode layers GEL1, GEL2, GEL3, GEL4, GEL5, GEL6, GEL7, GEL8, GEL9, GEL10 may be formed in a space surrounded by the charge storage layers 116. Therefore, heights of the plurality of gate electrode layers GEL1, GEL2, GEL3, GEL4, GEL5, GEL6, GEL7, GEL8, GEL9, GEL10 from the substrate 111 may be different from each other. In FIGS. 2, 3 and 4, the memory block BLKa is illustrated to include first through ten-th gate electrode layers GEL1, GEL2, GEL3, GEL4, GEL5, GEL6, GEL7, GEL8, GEL9, GEL10 as an example.

In some exemplary embodiments, the plurality of gate electrode layers GEL1, GEL2, GEL3, GEL4, GEL5, GEL6, GEL7, GEL8, GEL9, GEL10 may include a metallic conductive material such as tungsten.

In other exemplary embodiments, the plurality of gate electrode layers GEL1, GEL2, GEL3, GEL4, GEL5, GEL6, GEL7, GEL8, GEL9, GEL10 may include a nonmetallic conductive material such as polysilicon.

The plurality of gate electrode layers GEL1, GEL2, GEL3, GEL4, GEL5, GEL6, GEL7, GEL8, GEL9, GEL10 may extend along the first direction.

Therefore, as illustrated in FIGS. 3 and 4, the plurality of insulation layers 112, 112a and the plurality of gate electrode layers GEL1, GEL2, GEL3, GEL4, GEL5, GEL6, GEL7, GEL8, GEL9, GEL10 may be arranged alternately along the third direction, which is a direction perpendicular to the substrate 111, and the charge storage layers 116 may be formed between the plurality of insulation layers 112, 112a and the plurality of gate electrode layers GEL1, GEL2, GEL3, GEL4, GEL5, GEL6, GEL7, GEL8, GEL9, GEL10. In addition, the plurality of gate electrode layers GEL1, GEL2, GEL3, GEL4, GEL5, GEL6, GEL7, GEL8, GEL9, GEL10, the charge storage layers 116 and the channel layers 114 may be arranged sequentially along the second direction.

The plurality of gate electrode layers GEL1, GEL2, GEL3, GEL4, GEL5, GEL6, GEL7, GEL8, GEL9, GEL10 may be separated on the plurality of doping regions 121, 122, 123 by word line cuts WL CUT. The word line cuts WL CUT may expose the plurality of doping regions 121, 122, 123. The word line cuts WL CUT may extend along the first direction.

In some exemplary embodiments, a charge storage layer 116 formed on an upper surface of an uppermost insulation layer among the plurality of insulation layers 112, 112a may be removed.

A plurality of drains 130 may be formed on the plurality of pillars PL11, PL12, PL21, PL22, respectively. In some exemplary embodiments, the plurality of drains 130 may include a semiconductor material (e.g., silicon) having the second conductivity type. For example, the plurality of drains 130 may include an n-type semiconductor material. Hereinafter, it is assumed that the plurality of drains 130 is n-type. However, exemplary embodiments are not limited thereto.

A plurality of bit lines BL1, BL2, which extend in the second direction and are spaced apart along the first direction, may be formed on the plurality of drains 130. In some exemplary embodiments, the plurality of bit lines BL1, BL2 and the plurality of drains 130 may be connected via contact plugs.

In some exemplary embodiments, the plurality of bit lines BL1, BL2 may include a metallic conductive material.

In other exemplary embodiments, the plurality of bit lines BL1, BL2 may include a nonmetallic conductive material such as polysilicon.

Each of the plurality of pillars PL11, PL12, PL21, PL22 together with adjacent charge storage layers 116 and adjacent gate electrode layers GEL1, GEL2, GEL3, GEL4, GEL5, GEL6, GEL7, GEL8, GEL9, GEL10 may constitute one cell string. As illustrated in FIGS. 2, 3 and 4, since the plurality of pillars PL11, PL12, PL21, PL22 are formed on the substrate 111, the memory block BLKa may include a plurality of cell strings.

Each of the plurality of cell strings may include a plurality of cell transistors CT stacked in a direction perpendicular to the substrate 111, which is the third direction. Each of the plurality of gate electrode layers GEL1, GEL2, GEL3, GEL4, GEL5, GEL6, GEL7, GEL8, GEL9, GEL10 may act as a gate electrode of the cell transistor CT, and the channel layer 114 included in each of the plurality of pillars PL11, PL12, PL21, PL22 may act as a body of the cell transistor CT.

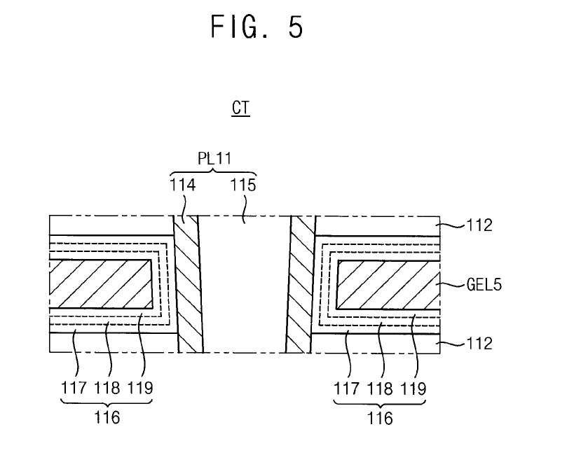

FIG. 5 is a diagram illustrating one of cell transistors included in a memory block of FIGS. 2, 3 and 4 according to an exemplary embodiment of the present inventive concept.

In FIG. 5, a cell transistor CT, which corresponds to a pillar PL11 and includes a fifth gate electrode layer GEL5, is illustrated as an example.

Referring to FIG. 5, the cell transistor CT may include the fifth gate electrode layer GEL5, a portion of the pillar PL11 adjacent to the fifth gate electrode layer GEL5, and the charge storage layer 116 formed between the fifth gate electrode layer GEL5 and the pillar PL11.

The channel layer 114 included in the pillar PL11 may include the same p-type silicon as the substrate 111. The channel layer 114 may act as a body of the cell transistor CT. Since the channel layer 114 is formed in a direction perpendicular to the substrate 111, the channel layer 114 may act as a vertical body of the cell transistor CT. A vertical channel may be formed at the channel layer 114 when the cell transistor CT operates.

The charge storage layer 116 may include the first through third sub insulation layers 117, 118, 119.

The first sub insulation layer 117 may be formed adjacent to the pillar PL11. The first sub insulation layer 117 may act as a tunneling insulation layer of the cell transistor CT. In some exemplary embodiments, the first sub insulation layer 117 may include a thermal oxide layer. In other exemplary embodiments, the first sub insulation layer 117 may include a silicon oxide layer.

The second sub insulation layer 118 may store charges tunneling from the channel layer 114 through the first sub insulation layer 117. For example, the second sub insulation layer 118 may act as a charge trap layer of the cell transistor CT. In some exemplary embodiments, the second sub insulation layer 118 may include a nitride layer. In other exemplary embodiments, the second sub insulation layer 118 may include a metal oxide layer.

The third sub insulation layer 119 may be formed adjacent to the fifth gate electrode layer GEL5. The third sub insulation layer 119 may act as a blocking insulation layer of the cell transistor CT. The third sub insulation layer 119 may be formed of a single layer or multiple layers. The third sub insulation layer 119 may be a high dielectric layer having a dielectric constant larger than those of the first and second sub insulation layers 117, 118. In some exemplary embodiments, the third sub insulation layer 119 may include a silicon oxide layer.

In some exemplary embodiments, the first through third sub insulation layers 117, 118, 119 may constitute oxide-nitride-oxide (ONO).

The fifth gate electrode layer GEL5 may act as a gate electrode of the cell transistor CT.

Therefore, the plurality of gate electrode layers GEL1, GEL2, GEL3, GEL4, GEL5, GEL6, GEL7, GEL8, GEL9, GEL10 acting as gate electrodes, the third sub insulation layers 119 acting as block insulation layers, the second sub insulation layers 118 acting as charge trap layers, the first sub insulation layers 117 acting as tunneling insulation layers, and the channel layers 114 acting as vertical bodies may constitute the cell transistors CT stacked in a direction perpendicular to the substrate 111.

Each of the cell transistors CT may have a cylindrical shape centered on a corresponding one of the plurality of pillars PL11, PL12, PL21, PL22.

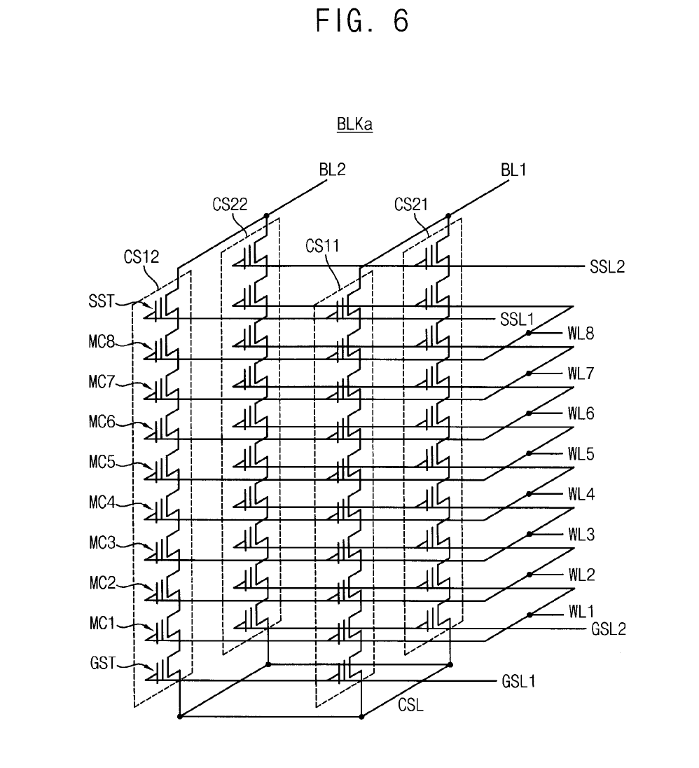

As will described below with reference to FIG. 6, the cell transistors CT included in the memory block BLKa may be used for different purposes according to the height.

In some exemplary embodiments, among the cell transistors CT, at least one cell transistor placed at an upper portion may be used as a string selection transistor SST. For example, the cell transistor CT including the ten-th gate electrode layer GEL10 may operate as the string selection transistor SST. In some exemplary embodiments, the charge storage layer 116 may not be formed in the cell transistor CT operating as the string selection transistor SST.

In some exemplary embodiments, among the cell transistors CT, at least one cell transistor placed at a lower portion may be used as a ground selection transistor GST. For example, the cell transistor CT including the first gate electrode layer GEL1 may operate as the ground selection transistor GST. In some exemplary embodiments, the charge storage layer 116 may not be formed in the cell transistor CT operating as the ground selection transistor GST.

In some exemplary embodiments, among the cell transistors CT, cell transistors placed between the at least one string selection transistor SST and the at least one ground selection transistor GST may be used as memory cells. For example, the cell transistors CT including the second through nin-th gate electrode layers GEL2, GEL3, GEL4, GEL5, GEL6, GEL7, GEL8, GEL9 may operate as first through eighth memory cells MC1, MC2, MC3, MC4, MC5, MC6, MC7, MC8, respectively.

Each of the plurality of gate electrode layers GEL1, GEL2, GEL3, GEL4, GEL5, GEL6, GEL7, GEL8, GEL9, GEL10 may be connected to one of the string selection line SSL, the plurality of word lines WL1, WL2, WL3, WL4, WL5, WL6, WL7, WL8, and the ground selection line GSL according to the height.

In some exemplary embodiments, the ten-th gate electrode layer GEL10, which corresponds to a gate electrode of the string selection transistor SST, may be connected to the string selection line SSL. The first gate electrode layer GEL1, which corresponds to a gate electrode of the ground selection transistor GST, may be connected to the ground selection line GSL. The second through nin-th gate electrode layers GEL2, GEL3, GEL4, GEL5, GEL6, GEL7, GEL8, GEL9, which correspond to gate electrodes of the memory cells, may be connected to first through eighth word lines WL1, WL2, WL3, WL4, WL5, WL6, WL7, WL8, respectively.

FIG. 6 is a circuit diagram illustrating an equivalent circuit of a memory block of FIGS. 2, 3 and 4 according to an exemplary embodiment of the present inventive concept.

Referring to FIGS. 2 to 6, the plurality of doping regions 121, 122, 123 may be connected to a common source line CSL.

A plurality of cell strings CS11, CS12, CS21, CS22 may be formed between the plurality of bit lines BL1, BL2 and the common source line CSL. Cell strings CS11, CS21 may be coupled between the first bit lines BL1 and the common source line CSL. Cell strings CS12, CS22 may be coupled between the second bit lines BL2 and the common source line CSL.

The plurality of cell strings CS11, CS12, CS21, CS22 illustrated in FIG. 6 may correspond to the plurality of pillars PL11, PL12, PL21, PL22, respectively. For example, four pillars PL11, PL12, PL21, PL22, the plurality of gate electrode layers GEL1, GEL2, GEL3, GEL4, GEL5, GEL6, GEL7, GEL8, GEL9, GEL10, and the charge storage layers 116 may form four cell strings CS11, CS12, CS21, CS22.

In some exemplary embodiments, the first gate electrode layer GEL1 together with the charge storage layers 116 and the plurality of pillars PL11, PL12, PL21, PL22 may constitute the ground selection transistors GST. In some exemplary embodiments, the first gate electrode layer GEL1, which corresponds to the gate electrodes of the ground selection transistors GST, may be connected to the ground selection lines GSL1, GSL2. For example, the ground selection transistors GST arranged along the first direction may be connected to a same ground selection line, and the ground selection transistors GST spaced apart along the second direction may be connected to ground selection lines different from each other. In other exemplary embodiments, all ground selection transistors GST including the first gate electrode layer GEL1 may be connected to a same ground selection line.

In some exemplary embodiments, the second through nin-th gate electrode layers GEL2, GEL3, GEL4, GEL5, GEL6, GEL7, GEL8, GEL9 together with the charge storage layers 116 and the plurality of pillars PL11, PL12, PL21, PL22 may constitute the first through eighth memory cells MC1, MC2, MC3, MC4, MC5, MC6, MC7, MC8. The second through nin-th gate electrode layers GEL2, GEL3, GEL4, GEL5, GEL6, GEL7, GEL8, GEL9, which correspond to the gate electrodes of the first through eighth memory cells MC1, MC2, MC3, MC4, MC5, MC6, MC7, MC8, may be connected to the first through eighth word lines WL1, WL2, WL3, WL4, WL5, WL6, WL7, WL8, respectively. That is, memory cells formed at a same height may be commonly connected to a same word line. Therefore, when a voltage is applied to a selected word line among the plurality of word lines WL1, WL2, WL3, WL4, WL5, WL6, WL7, WL8, the voltage may be applied to all memory cells connected to the selected word line in the plurality of cell strings CS11, CS12, CS21, CS22.

In some exemplary embodiments, the ten-th gate electrode layer GEL10 together with the charge storage layers 116 and the plurality of pillars PL11, PL12, PL21, PL22 may constitute the string selection transistors SST. The ten-th gate electrode layer GEL10, which corresponds to the gate electrodes of the string selection transistors SST, may be connected to the string selection lines SSL1, SSL2. For example, the string selection transistors SST arranged along the first direction may be connected to a same string selection line, and the string selection transistors SST spaced apart along the second direction may be connected to string selection lines different from each other.

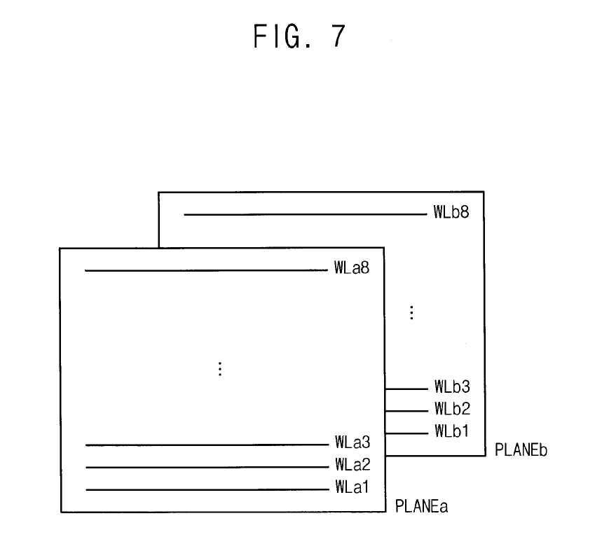

FIG. 7 is a diagram illustrating a plane structure of an equivalent circuit diagram of FIG. 6 according to an exemplary embodiment of the present inventive concept.

Referring to FIGS. 2 to 7, the equivalent circuit diagram of FIG. 6 may include two planes. In FIG. 6, the cell strings CS11, CS12 may constitute a first plane PLANEa, and the cell strings CS21, CS22 may constitute a second plane PLANEb. The first word line WL1 may be divided into first sub word lines WLa1, WLb1 according to planes. The second word line WL2 may be divided into second sub word lines WLa2, WLb2 according to planes. The third word line WL3 may be divided into third sub word lines WLa3, WLb3 according to planes. The fourth word line WL4 may be divided into fourth sub word lines WLa4, WLb4 according to planes. The fifth word line WL5 may be divided into fifth sub word lines WLa5, WLb5 according to planes. The sixth word line WL6 may be divided into sixth sub word lines WLa6, WLb6 according to planes. The seven-th word line WL7 may be divided into seven-th sub word lines WLa7, WLb7 according to planes. The eighth word line WL8 may be divided into eighth sub word lines WLa8, WLb8 according to planes.

Cell strings arranged in a same plane may be connected to a same string selection line, and cell strings arranged in different planes may be connected to different string selection lines from each other. For example, the cell strings CS11, CS12 arranged in the first plane PLANEa may be connected to a first string selection line SSL1, and the cell strings CS21, CS22 arranged in the second plane PLANEb may be connected to a second string selection line SSL2.

Cell strings may be selected by a unit of a plane by selecting one of the string selection lines SSL1, SSL2. For example, when the first string selection line SSL1 is selected, cell strings CS11, CS12 connected to the first string selection line SSL1 may be electrically connected to the plurality of bit lines BL1, BL2, and cell strings CS21, CS22 connected to the second string selection line SSL2, which is unselected, may be electrically disconnected from the plurality of bit lines BL1, BL2.

Cell strings arranged along the second direction may be connected to a same bit line, and cell strings spaced apart along the first direction may be connected to bit lines different from each other. For example, the cell strings CS11, CS21 may be connected to a first bit line BL1, and the cell strings CS12, CS22 may be connected to a second bit line BL2.

In FIGS. 2 to 6, each cell string is illustrated to include one string selection transistor SST, one ground selection transistor GST, and the first through eighth memory cells MC1, MC2, MC3, MC4, MC5, MC6, MC7, MC8 arranged between the string selection transistor SST and the ground selection transistor GST, as an example. However, the number of the string selection transistors SST, the ground selection transistors GST and the memory cells MC1, MC2, MC3, MC4, MC5, MC6, MC7, MC8 are not limited thereto.

As described above, each of the memory cells MC1, MC2, MC3, MC4, MC5, MC6, MC7, MC8 may include a corresponding gate electrode layer GEL2, GEL3, GEL4, GEL5, GEL6, GEL7, GEL8, GEL9, the charge storage layer 116 and the channel layer 114. The program operation and the erase operation may be performed on each of the memory cells MC1, MC2, MC3, MC4, MC5, MC6, MC7, MC8 by applying an electric field between a corresponding gate electrode layer GEL2, GEL3, GEL4, GEL5, GEL6, GEL7, GEL8, GEL9 and the channel layer 114 such that charges may tunnel between the charge storage layer 116 and the channel layer 114. Since the channel layer 114 is electrically connected to the substrate 111, the program operation and the erase operation may be performed on each of the memory cells MC1, MC2, MC3, MC4, MC5, MC6, MC7, MC8 by applying different voltages having different magnitudes to a corresponding gate electrode layer GEL2, GEL3, GEL4, GEL5, GEL6, GEL7, GEL8, GEL9 and the substrate 111.

In some exemplary embodiments, the program operation may be performed on each of the memory cells MC1, MC2, MC3, MC4, MC5, MC6, MC7, MC8 by applying a voltage to a corresponding gate electrode layer GEL2, GEL3, GEL4, GEL5, GEL6, GEL7, GEL8, GEL9 that is higher than a voltage applied to the substrate 111 such that negative charges may tunnel from the channel layer 114 to the charge storage layer 116.

In some exemplary embodiments, the erase operation may be performed on each of the memory cells MC1, MC2, MC3, MC4, MC5, MC6, MC7, MC8 by applying a voltage to the substrate 111 that is higher than a voltage applied to a corresponding gate electrode layer GEL2, GEL3, GEL4, GEL5, GEL6, GEL7, GEL8, GEL9 such that negative charges may tunnel from the charge storage layer 116 to the channel layer 114.

In other exemplary embodiments, the erase operation may be performed on each of the memory cells MC1, MC2, MC3, MC4, MC5, MC6, MC7, MC8 by applying a voltage to the substrate 111 that is higher than a voltage applied to a corresponding gate electrode layer GEL2, GEL3, GEL4, GEL5, GEL6, GEL7, GEL8, GEL9 such that positive charges may tunnel from the channel layer 114 to the charge storage layer 116.

Each of the plurality of memory cells MC1, MC2, MC3, MC4, MC5, MC6, MC7, MC8 may have a cylindrical shape centered on a corresponding one of the plurality of pillars PL11, PL12, PL21, PL22.

Since each of the plurality of pillars PL11, PL12, PL21, PL22 is formed by vertically patterning the plurality of insulation layers 112, 112a, a width of each of the plurality of pillars PL11, PL12, PL21, PL22 may be reduced as it gets closer to the bottom portion of the pillar. For example, as illustrated in FIG. 4, a diameter Wb of lower portion of the plurality of pillars PL11, PL12, PL21, PL22 is smaller than a diameter Wt of upper portion of the plurality of pillars PL11, PL12, PL21, PL22 such that each of the plurality of pillars PL11, PL12, PL21, PL22 may be a V-shaped cylinder having an inclination angle a.

Therefore, diameters of portions of the plurality of pillars PL11, PL12, PL21, PL22 on which the plurality of memory cells MC1, MC2, MC3, MC4, MC5, MC6, MC7, MC8 are formed may be different from each other according to the height from the substrate 111. That is, diameters of the plurality of memory cells MC1, MC2, MC3, MC4, MC5, MC6, MC7, MC8 may be different from each other according to their respective height from the substrate 111. For example, among the plurality of memory cells MC1, MC2, MC3, MC4, MC5, MC6, MC7, MC8, a memory cell arranged at a lower portion of the plurality of pillars PL11, PL12, PL21, PL22 may have a relatively small diameter and a memory cell arranged at an upper portion of the plurality of pillars PL11, PL12, PL21, PL22 may have a relatively large diameter.

Therefore, although a same voltage is applied to the plurality of gate electrode layers GEL2, GEL3, GEL4, GEL5, GEL6, GEL7, GEL8, GEL9, intensities of electric fields formed between the plurality of gate electrode layers GEL2, GEL3, GEL4, GEL5, GEL6, GEL7, GEL8, GEL9 and the channel layer 114 may be different from each other. As such, program speeds of the plurality of memory cells MC1, MC2, MC3, MC4, MC5, MC6, MC7, MC8 may be different from each other according to the height from the substrate 111, and erase speeds of the plurality of memory cells MC1, MC2, MC3, MC4, MC5, MC6, MC7, MC8 may be different from each other according to the height from the substrate 111. For example, program speeds and erase speeds of a memory cell formed at a relatively lower portion may be greater than program speeds and erase speeds of a memory cell formed at a relatively higher portion.

Since the memory cell array 100 may perform the erase operation by a unit of a memory block, a threshold voltage distribution of the plurality of memory cells MC1, MC2, MC3, MC4, MC5, MC6, MC7, MC8 in an erased state may be widened if the erase speeds of the plurality of memory cells MC1, MC2, MC3, MC4, MC5, MC6, MC7, MC8 are different from each other according to the height from the substrate 111.

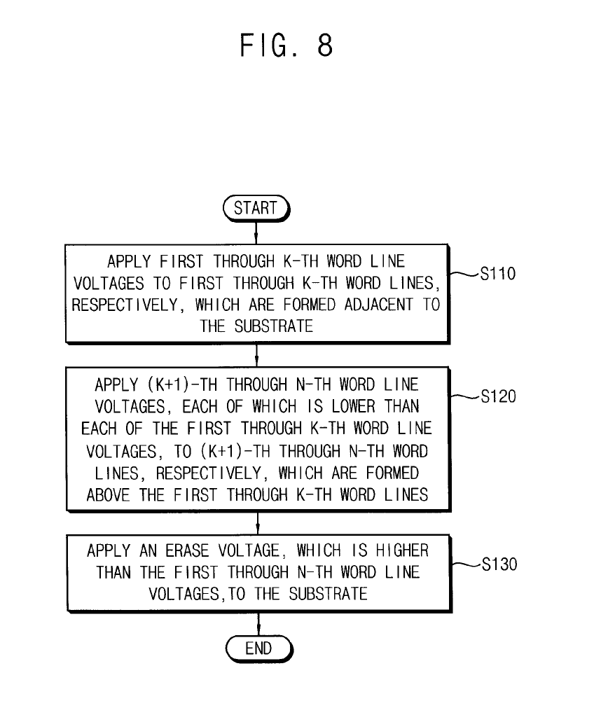

FIG. 8 is a flow chart illustrating a method of erasing a nonvolatile memory device according to the exemplary embodiments.

A nonvolatile memory device performing the method of erasing of FIG. 8 includes a substrate and first through n-th word lines stacked in a direction perpendicular to the substrate. Here, the first word line corresponds to a lowermost word line among the first through n-th word lines, and the n-th word line corresponds to an uppermost word line among the first through n-th word lines. Here, n represents an integer equal to or greater than two.

For example, the method of erasing of FIG. 8 may be performed by the nonvolatile memory device 10 of FIG. 1.

Hereinafter, the method of erasing the nonvolatile memory device 10 will be described with reference to FIGS. 1 to 8.

Referring to FIG. 8, first through k-th word line voltages are applied (step S110) to first through k-th word lines WL1˜WLk, respectively, which are formed adjacent to the substrate 111, among the first through n-th word lines WL1˜WLn. (k+1)-th through n-th word line voltages, each of which is lower than each of the first through k-th word line voltages, are applied (step S120) to (k+1)-th through n-th word lines WL(k+1)˜WLn, respectively, which are formed above the first through k-th word lines WL1˜WLk, among the first through n-th word lines WL1˜WLn. Here, k represents a positive integer smaller than n.

An erase voltage, which is higher than the first through n-th word line voltages, is applied (step S130) to the substrate 111.

The string selection line SSL, which is connected to the string selection transistor SST, the ground selection line GSL, which is connected to the ground selection transistor GST, the plurality of bit lines BL1˜BLm, and the common source line CSL may be floated.

In some exemplary embodiments, the first through n-th word line voltages may be provided from the voltage generation unit 400. For example, the voltage generation unit 400 may generate the first through n-th word line voltages and provide the first through n-th word line voltages to the address decoder 200, and the address decoder 200 may apply the first through n-th word line voltages to the first through n-th word lines WL1˜WLn, respectively, under a control of the control unit 500.

In some exemplary embodiments, the erase voltage may be provided from the voltage generation unit 400. For example, the voltage generation unit 400 may apply the erase voltage to the substrate 111 under a control of the control unit 500.

Since the first through n-th word lines WL1˜WLn are maintained at the first through n-th word line voltages, respectively, and the substrate 111 receives the erase voltage, which is higher than the first through n-th word line voltages, an electric field may be formed in the memory cells MC1˜MCn (i.e., MC1, MC2, . . . MCn) connected to the first through n-th word lines WL1˜WLn, respectively, such that the erase operation may be performed on the memory cells MC1˜MCn.

In some exemplary embodiments, the erase operation may be performed on the memory cells MC1˜MCn by tunneling negative charges from the charge storage layer 116 included in the memory cells MC1˜MCn to the channel layer 114.

In other exemplary embodiments, the erase operation may be performed on the memory cells MC1˜MCn by tunneling positive charges from the channel layer 114 to the charge storage layer 116 included in the memory cells MC1˜MCn.

As described above with reference to FIGS. 1 to 7, the plurality of pillars PL11, PL12, PL21, PL22 may be a V-shaped cylinder having a diameter reducing as it gets closer to the bottom portion. Therefore, when the first through n-th word line voltages are the same, an erase speed of a memory cell formed at a relatively lower portion among the memory cells MC1˜MCn may be greater than an erase speed of a memory cell formed at a relatively higher portion among the memory cells MC1˜MCn. Since the memory cell array 100 included in the nonvolatile memory device 10 may perform the erase operation by a unit of a memory block, a threshold voltage distribution of the memory cells MC1˜MCn in an erased state may be widened if the erase speeds of the memory cells MC1˜MCn are different from each other according to the height from the substrate 111. When the threshold voltage distribution of the memory cells MC1˜MCn in an erased state becomes widened, a threshold voltage distribution of the memory cells MC1˜MCn in a programmed state also becomes widened since the program operation is performed on the memory cells MC1˜MCn in an erased state, such that word line coupling may increase.

However, as described above, in the method of erasing the nonvolatile memory device 10, each of the first through k-th word line voltages, which are applied to the first through k-th word lines WL1˜WLk, respectively, that are formed at relatively small heights, is higher than each of the (k+1)-th through n-th word line voltages, which are applied to the (k+1)-th through n-th word lines WL(k+1)˜WLn, respectively, that are formed at relatively large heights. Therefore, during the erase operation, voltage differences between the channel layer 114 and the gate electrode layers of the memory cells MC1˜MCk, which are formed at relatively small heights, may be smaller than voltage differences between the channel layer 114 and the gate electrode layers of the memory cells MC(k+1)˜MCn, which are formed at relatively large heights. Therefore, differences between the erase speeds of the memory cells MC1˜MCn according to the heights from the substrate 111 may be reduced. As such, the method of erasing the nonvolatile memory device 10 according to exemplary embodiments may effectively reduce the threshold voltage distribution of the memory cells MC1˜MCn in the erased state after the erase operation is performed on the memory cells MC1˜MCn.

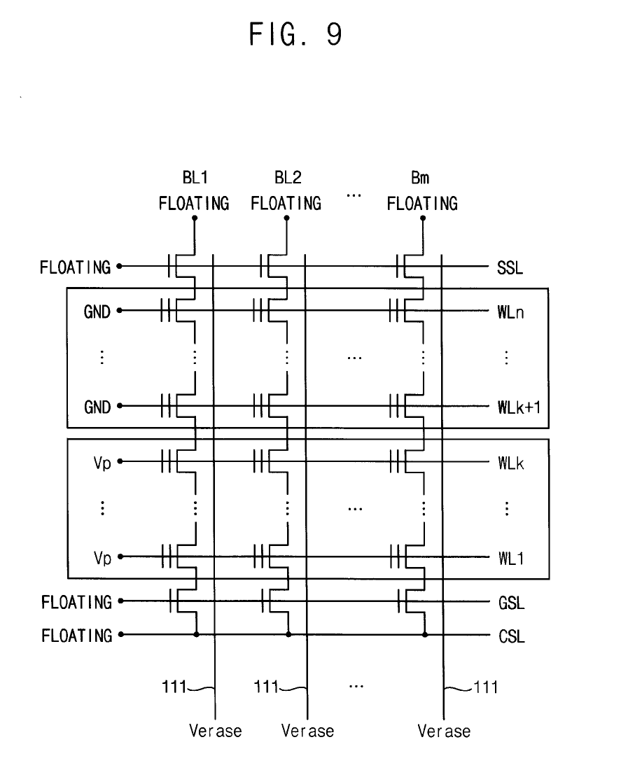

FIG. 9 is a circuit diagram for describing the method of erasing the nonvolatile memory device of FIG. 8 according to an exemplary embodiment of the present inventive concept.

For ease of explanation, only one of the planes included in the memory block BLKa is illustrated in FIG. 9.

As illustrated in FIG. 9, the first through k-th word line voltages, which are applied to the first through k-th word lines WL1˜WLk, respectively, that are formed at relatively small heights, may be a same positive voltage Vp, and the (k+1)-th through n-th word line voltages, which are applied to the (k+1)-th through n-th word lines WL(k+1)˜WLn, respectively, that are formed at relatively large heights, may be a ground voltage GND. For example, a level of the positive voltage Vp may be 1V, and a level of the erase voltage, which is applied to the substrate 111, may be 12V.

Therefore, voltage differences between the channel layer 114 and the gate electrode layers of the memory cells MC1˜MCk, which are formed at relatively small heights, may be smaller than voltage differences between the channel layer 114 and the gate electrode layers of the memory cells MC(k+1)˜MCn, which are formed at relatively large heights, such that differences between the erase speeds of the memory cells MC1˜MCn according to the heights from the substrate 111 may be reduced. As such, after the erase operation is performed on the memory cells MC1˜MCn, the threshold voltage distribution of the memory cells MC1˜MCn in the erased state may be effectively reduced.

FIG. 10 is a circuit diagram for describing the method of erasing the nonvolatile memory device of FIG. 8 according to an exemplary embodiment of the present inventive concept.

For ease of explanation, only one of the planes included in the memory block BLKa is illustrated in FIG. 10.

As illustrated in FIG. 10, the first through k-th word line voltages, which are applied to the first through k-th word lines WL1˜WLk, respectively, that are formed at relatively small heights, may be the ground voltage GND, and the (k+1)-th through n-th word line voltages, which are applied to the (k+1)-th through n-th word lines WL(k+1)˜WLn, respectively, that are formed at relatively large heights, may be a same negative voltage Vn. For example, a level of the negative voltage Vn may be −2V, and a level of the erase voltage, which is applied to the substrate 111, may be 12V.

Therefore, voltage differences between the channel layer 114 and the gate electrode layers of the memory cells MC1˜MCk, which are formed at relatively small heights, may be smaller than voltage differences between the channel layer 114 and the gate electrode layers of the memory cells MC(k+1)˜MCn, which are formed at relatively large heights, such that differences between the erase speeds of the memory cells MC1˜MCn according to the heights from the substrate 111 may be reduced. As such, after the erase operation is performed on the memory cells MC1˜MCn, the threshold voltage distribution of the memory cells MC1˜MCn in the erased state may be effectively reduced.

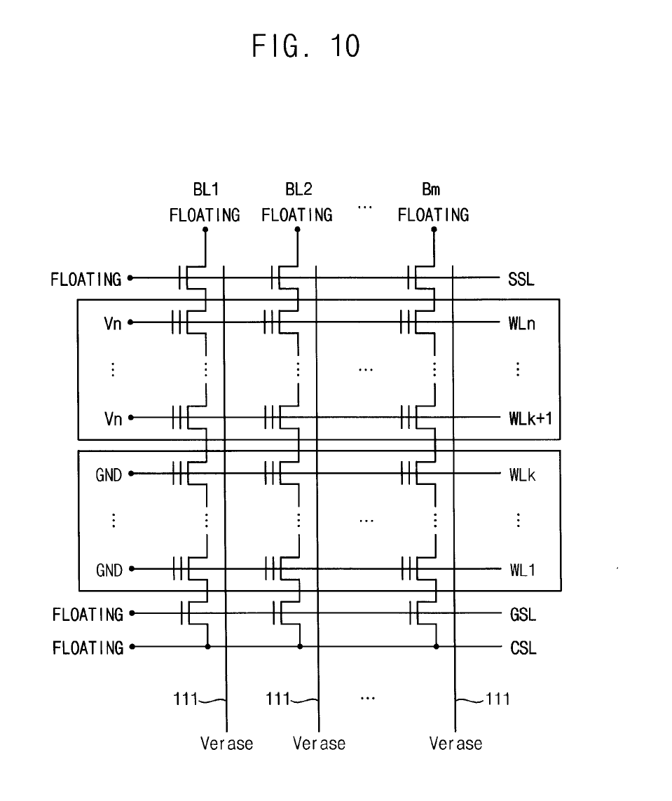

FIG. 11 is a circuit diagram for describing the method of erasing the nonvolatile memory device of FIG. 8 according to an exemplary embodiment of the present inventive concept.

For ease of explanation, only one of the planes included in the memory block BLKa is illustrated in FIG. 11.

As illustrated in FIG. 11, the first through k-th word line voltages, which are applied to the first through k-th word lines WL1˜WLk, respectively, that are formed at relatively small heights, may be first through k-th positive voltages Vp1˜Vpk (i.e., Vp1, Vp2, Vpk), respectively, and the (k+1)-th through n-th word line voltages, which are applied to the (k+1)-th through n-th word lines WL(k+1)˜WLn, respectively, that are formed at relatively large heights, may be the ground voltage GND. In some exemplary embodiments, i-th word line voltage is equal to or higher than j-th word line voltage, where i and j are positive integers equal to or smaller than k and j is greater than i. That is, a magnitude of the first positive voltage Vp1 is the greatest among the first through k-th positive voltages Vp1˜Vpk, and a magnitude of the k-th positive voltage Vpk is the smallest among the first through k-th positive voltages Vp1˜Vpk.

Therefore, differences between the erase speeds of the memory cells MC1˜MCn according to the heights from the substrate 111 may be further reduced. As such, after the erase operation is performed on the memory cells MC1˜MCn, the threshold voltage distribution of the memory cells MC1˜MCn in the erased state may be effectively reduced.

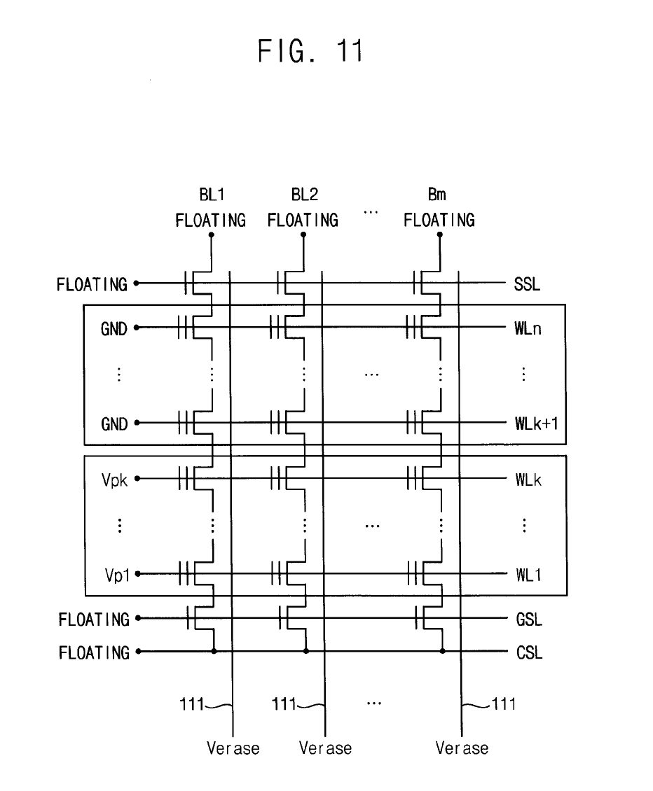

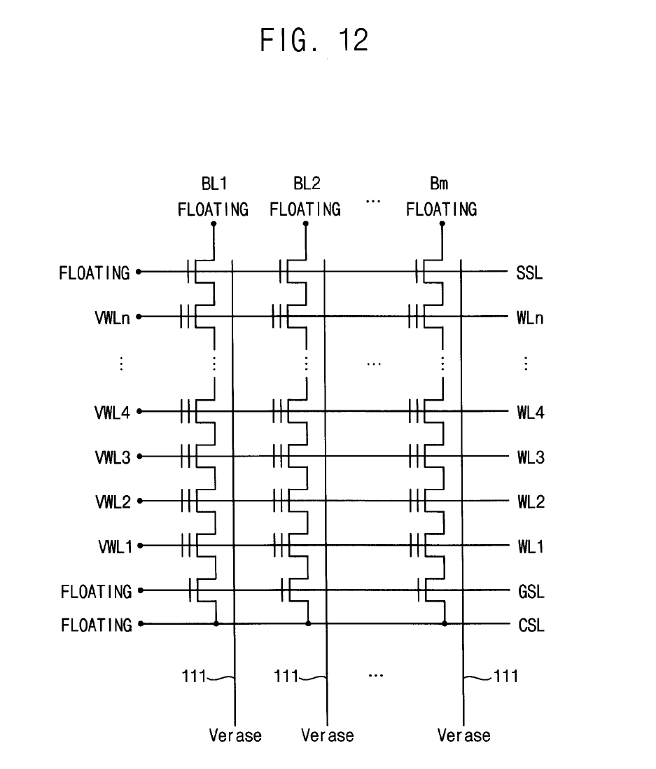

FIG. 12 is a circuit diagram for describing the method of erasing the nonvolatile memory device of FIG. 8 according to an exemplary embodiment of the present inventive concept.

For ease of explanation, only one of the planes included in the memory block BLKa is illustrated in FIG. 12.

As illustrated in FIG. 12, the first through n-th word line voltages VWL1˜VWLn (i.e., VWL1, VWL2, . . . VWLn) may be applied to the first through n-th word lines WL1˜WLn, respectively. In some exemplary embodiments, s-th word line voltage VWLs is equal to or higher than t-th word line voltage VWLt, where s and t are positive integers equal to or smaller than n and t is greater than s.

Therefore, differences between the erase speeds of the memory cells MC1˜MCn according to the heights from the substrate 111 may be further reduced by applying a relative high voltage to a word line arranged at a relatively low height and applying a relative low voltage to a word line arranged at a relatively high height. As such, after the erase operation is performed on the memory cells MC1˜MCn, the threshold voltage distribution of the memory cells MC1˜MCn in the erased state may be effectively reduced.

As described above with reference to FIGS. 1 to 7, since each of the plurality of pillars PL11, PL12, PL21, PL22 is formed by vertically patterning the plurality of insulation layers 112, 112a, the plurality of pillars PL11, PL12, PL21, PL22 may be a V-shaped cylinder having a diameter reducing as it gets closer to the bottom portion. In a process of vertical patterning, a portion of each of the plurality of pillars PL11, PL12, PL21, PL22 may have an a typical shape, such as a protruded shape, an oval shape, etc., instead of a circular shape. When the first through n-th word line voltages are the same, a magnitude of an electric field formed in a memory cell having an a typical shape may be relatively greater than a magnitude of an electric field formed in other memory cells. Therefore, an erase speed of a memory cell having an a typical shape may be relatively greater than an erase speed of other memory cells.

In some exemplary embodiments, m-th word line voltage, which is applied to m-th memory cell, may be higher than the rest of the first through n-th word line voltages when the m-th memory cell has an a typical shape. Here, m represents a positive integer equal to or smaller than n. That is, a word line voltage having a relatively high level may be applied to a word line connected to a memory cell having an a typical shape, such that differences between the erase speeds of the memory cells MC1˜MCn according to the heights from the substrate 111 may be reduced. As such, after the erase operation is performed on the memory cells MC1˜MCn, the threshold voltage distribution of the memory cells MC1˜MCn in the erased state may be effectively reduced.

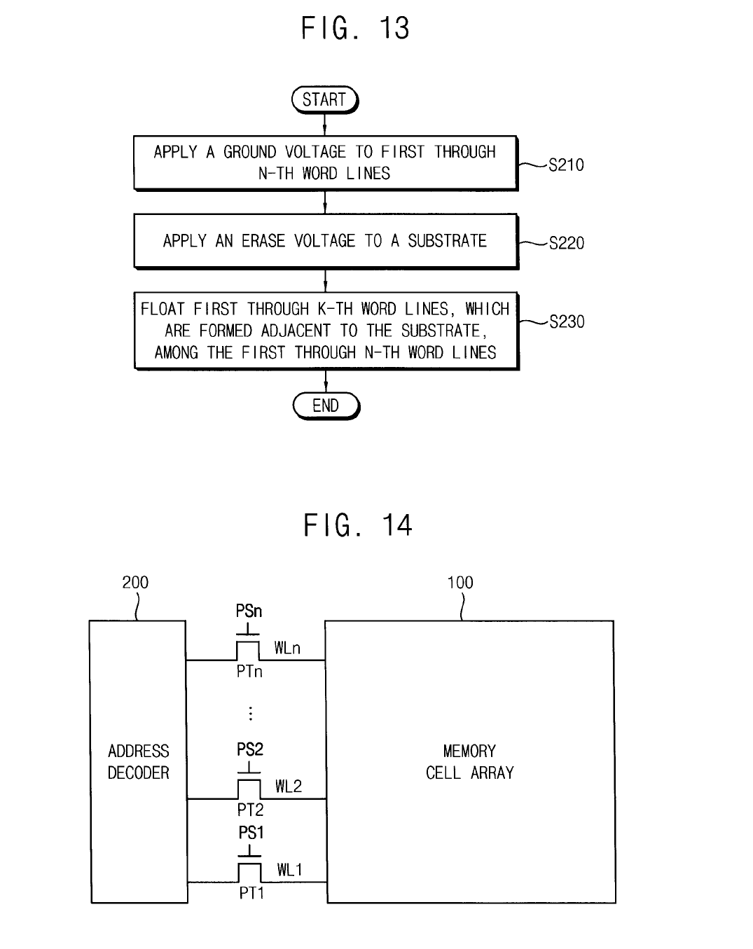

FIG. 13 is a flow chart illustrating a method of erasing a nonvolatile memory device according to exemplary embodiments.

A nonvolatile memory device performing the method of erasing of FIG. 13 includes a substrate and first through n-th word lines stacked in a direction perpendicular to the substrate. Here, the first word line corresponds to a lowermost word line among the first through n-th word lines, and the n-th word line corresponds to an uppermost word line among the first through n-th word lines. Here, n represents an integer equal to or greater than two.

For example, the method of erasing of FIG. 13 may be performed by the nonvolatile memory device 10 of FIG. 1.

Hereinafter, the method of erasing the nonvolatile memory device 10 will be described with reference to FIGS. 1 to 7 and 13.

Referring to FIG. 13, the ground voltage GND is applied (step S210) to the first through n-th word lines WL1˜WLn, and an erase voltage is applied (step S220) to the substrate 111. The erase voltage may be a positive voltage having a relatively large level. After the erase voltage is applied to the substrate 111, first through k-th word lines WL1˜WLk, which are formed adjacent to the substrate 111, among the first through n-th word lines WL1˜WLn are floated (step S230). Here, k represents a positive integer equal to or smaller than n.

The string selection line SSL, which is connected to the string selection transistor SST, the ground selection line GSL, which is connected to the ground selection transistor GST, the plurality of bit lines BL1˜BLm, and the common source line CSL may be floated.

In some exemplary embodiments, the erase voltage may be provided from the voltage generation unit 400. For example, the voltage generation unit 400 may apply the erase voltage to the substrate 111 under a control of the control unit 500.

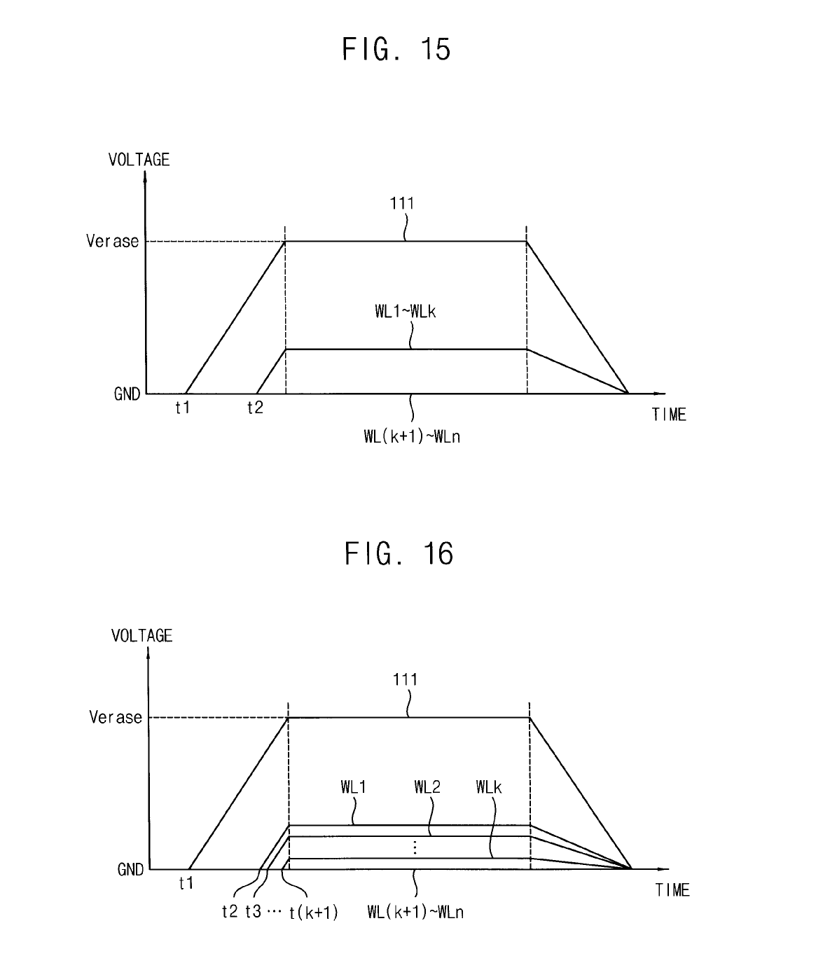

FIG. 14 is a circuit diagram illustrating an example of a word line connection between the address decoder and the memory cell array of FIG. 1. FIG. 15 is a graph for describing an example of the method of erasing the nonvolatile memory device of FIG. 13.

Referring to FIGS. 14 and 15, the first through n-th word lines WL1˜WLn, which are connected to the memory cell array 100, may be connected to the address decoder 200 through first through n-th pass transistors PT1˜PTn (i.e., PT1, PT2, . . . PTn), respectively.

First through n-th pass signals PS1˜PSn (i.e., PS1, PS2, . . . Psn) may be applied to gate electrodes of the first through n-th pass transistors PT1˜PTn, respectively. Each of the first through n-th pass transistors PT1˜PTn may be turned on when each of the first through n-th pass signals PS1˜PSn is activated, and each of the first through n-th pass transistors PT1˜PTn may be turned off when each of the first through n-th pass signals PS1˜PSn is deactivated.

In some exemplary embodiments, the first through n-th pass signals PS1˜PSn may be provided from the control unit 500.

In some exemplary embodiments, the address decoder 200 may apply the ground voltage GND to the first through n-th pass transistors PT1˜PTn, and the control unit 500 may provide the first through n-th pass signals PS1˜PSn being activated to the gate electrodes of the first through n-th pass transistors PT1˜PTn to turn on the first through n-th pass transistors PT1˜PTn. Therefore, the ground voltage GND may be applied to the first through n-th word lines WL1˜WLn through the first through n-th pass transistors PT1˜PTn, respectively.

At a first time t1, the voltage generation unit 400 may apply the erase voltage Verase to the substrate 111 under a control of the control unit 500.

Therefore, as illustrated in FIG. 15, a voltage of the substrate 111 may increase from ground voltage GND to the erase voltage Verase.

At a second time t2, the control unit 500 may deactivate the first through k-th pass signals PS1˜PSk, which are provided to the gate electrodes of the first through k-th pass transistors PT1˜PTk that are connected to the first through k-th word lines WL1˜WLk formed adjacent to the substrate 111, to turn off the first through k-th pass transistors PT1˜PTk. Therefore, the first through k-th word lines WL1˜WLk may be floated.

Therefore, as illustrated in FIG. 15, voltages of the first through k-th word lines WL1˜WLk may be maintained at the ground voltage GND before the first through k-th word lines WL1˜WLk are floated at the second time t2 since the first through k-th pass transistors PT1˜PTk are turned on before the first through k-th word lines WL1˜WLk are floated at the second time t2. However, after the first through k-th word lines WL1˜WLk are floated at the second time t2, a coupling effect may occur between the first through k-th word lines WL1˜WLk and the substrate 111. Therefore, after the first through k-th word lines WL1˜WLk are floated at the second time t2, the voltages of the first through k-th word lines WL1˜WLk may increase from the ground voltage GND as the voltage of the substrate 111 increases to the erase voltage Verase.

On the other hand, as illustrated in FIG. 15, voltages of the (k+1)-th through n-th word lines WL(k+1)˜WLn may be maintained at the ground voltage GND during the erase operation since the (k+1)-th through n-th pass transistors PT(k+1)˜PTn are maintained to be turned on during the erase operation.

As illustrated in FIG. 15, since the erase voltage Verase, which is applied to the substrate 111, is higher than the voltages of the first through n-th word lines WL1˜WLn, an electric field may be formed in the memory cells MC1˜MCn connected to the first through n-th word lines WL1˜WLn such that the erase operation may be performed on the memory cells MC1˜MCn.

In some exemplary embodiments, the erase operation may be performed on the memory cells MC1˜MCn by tunneling negative charges from the charge storage layer 116 included in the memory cells MC1˜MCn to the channel layer 114.

In other exemplary embodiments, the erase operation may be performed on the memory cells MC1˜MCn by tunneling positive charges from the channel layer 114 to the charge storage layer 116 included in the memory cells MC1˜MCn.

As described above with reference to FIGS. 1 to 7, the plurality of pillars PL11, PL12, PL21, PL22 may be a V-shaped cylinder having a diameter reducing as it gets closer to the bottom portion. Therefore, when the first through n-th word line voltages are the same, an erase speed of a memory cell formed at a relatively lower portion among the memory cells MC1˜MCn may be greater than an erase speed of a memory cell formed at a relatively higher portion among the memory cells MC1˜MCn. Since the memory cell array 100 included in the nonvolatile memory device 10 may perform the erase operation by a unit of a memory block, a threshold voltage distribution of the memory cells MC1˜MCn in an erased state may be widened if the erase speeds of the memory cells MC1˜MCn are different from each other according to the height from the substrate 111. When the threshold voltage distribution of the memory cells MC1 MCn in an erased state becomes widened, a threshold voltage distribution of the memory cells MC1˜MCn in a programmed state also becomes widened since the program operation is performed on the memory cells MC1˜MCn in an erased state, such that word line coupling may increase.

However, as described above, in the method of erasing the nonvolatile memory device 10, the voltages of the first through k-th word lines WL1˜WLk may be maintained at the ground voltage GND before the first through k-th word lines WL1˜WLk are floated at the second time t2 since the first through k-th pass transistors PT1˜PTk are turned on before the second time t2. However, after the first through k-th word lines WL1˜WLk are floated at the second time t2, a coupling effect may occur between the first through k-th word lines WL1˜WLk and the substrate 111 such that the voltages of the first through k-th word lines WL1˜WLk may increase from the ground voltage GND after the second time t2 due to the coupling effect as the voltage of the substrate 111 increases to the erase voltage Verase.

On the other hand, voltages of the (k+1)-th through n-th word lines WL(k+1)˜WLn may be maintained at the ground voltage GND during the erase operation since the (k+1)-th through n-th pass transistors PT(k+1)˜PTn are turned on during the erase operation.

The first through k-th word lines WL1˜WLk may be connected to the memory cells MC1˜MCk, which are formed at relatively small heights among the memory cells MC1˜MCn, and the (k+1)-th through n-th word lines WL(k+1)˜WLn may be connected to the memory cells MC(k+1)˜MCn, which are formed at relatively large heights among the memory cells MC1˜MCn. Therefore, during the erase operation, voltage differences between the channel layer 114 and the gate electrode layers of the memory cells MC1˜MCk may be smaller than voltage differences between the channel layer 114 and the gate electrode layers of the memory cells MC(k+1)˜MCn. Therefore, differences between the erase speeds of the memory cells MC1˜MCn according to the heights from the substrate 111 may be reduced. As such, the method of erasing the nonvolatile memory device 10 according to exemplary embodiments may effectively reduce the threshold voltage distribution of the memory cells MC1˜MCn in the erased state after the erase operation is performed on the memory cells MC1˜MCn.

In some exemplary embodiments, after the erase voltage Verase is applied to the substrate 111, the first through k-th word lines WL1˜WLk may be floated one by one in an order from the first word line WL1 to the k-th word line WLk.

FIG. 16 is a graph for describing the method of erasing a nonvolatile memory device of FIG. 13 according to an exemplary embodiment of the present inventive concept.

Referring to FIGS. 14 and 16, the address decoder 200 may apply the ground voltage GND to the first through n-th pass transistors PT1˜PTn, and the control unit 500 may provide the first through n-th pass signals PS1˜PSn being activated to the gate electrodes of the first through n-th pass transistors PT1˜PTn to turn on the first through n-th pass transistors PT1˜PTn. Therefore, the ground voltage GND may be applied to the first through n-th word lines WL1˜WLn through the first through n-th pass transistors PT1˜PTn, respectively.

At a first time t1, the voltage generation unit 400 may apply the erase voltage Verase to the substrate 111 under a control of the control unit 500.

Therefore, as illustrated in FIG. 16, a voltage of the substrate 111 may increase to the erase voltage Verase.

The control unit 500 may deactivate the first through k-th pass signals PS1˜PSk, which are provided to the gate electrodes of the first through k-th pass transistors PT1˜PTk that are connected to the first through k-th word lines WL1˜WLk formed adjacent to the substrate 111, at second through (k+1)-th times t2, t3, t(k+1), respectively, to turn off the first through k-th pass transistors PT1˜PTk one by one in an order from the first pass transistor PT1 to the k-th pass transistor PTk. Therefore, the first through k-th word lines WL1˜WLk may be floated one by one in an order from the first word line WL1 to the k-th word line WLk.

Therefore, as illustrated in FIG. 16, voltages of the first through k-th word lines WL1˜WLk may be maintained at the ground voltage GND before the first through k-th word lines WL1˜WLk are floated since the first through k-th pass transistors PT1˜PTk are turned on before the first through k-th word lines WL1˜WLk are floated. However, after each of the first through k-th word lines WL1˜WLk is floated, a coupling effect may occur between each of the first through k-th word lines WL1˜WLk and the substrate 111. Therefore, after each of the first through k-th word lines WL1˜WLk is floated, the voltages of the first through k-th word lines WL1˜WLk may increase from the ground voltage GND as the voltage of the substrate 111 increases to the erase voltage Verase.

On the other hand, as illustrated in FIG. 16, voltages of the (k+1)-th through n-th word lines WL(k+1)˜WLn may be maintained at the ground voltage GND during the erase operation since the (k+1)-th through n-th pass transistors PT(k+1)˜PTn are maintained to be turned on during the erase operation.

Therefore, during the erase operation, a voltage difference between the channel layer 114 and a gate electrode layer of a memory cell among the memory cells MC1˜MCk may become smaller as the memory cell is arranged at lower portion of the memory cells MC1˜MCk. Therefore, differences between the erase speeds of the memory cells MC1˜MCn according to the heights from the substrate 111 may be further reduced. As such, the method of erasing the nonvolatile memory device 10 according to exemplary embodiments may effectively reduce the threshold voltage distribution of the memory cells MC1˜MCn in the erased state after the erase operation is performed on the memory cells MC1˜MCn.

In some exemplary embodiments, the first through k-th word lines WL1˜WLk, which are formed adjacent to the substrate 111, among the first through n-th word lines WL1˜WLn may be floated when a reference time elapses from a time at which the erase voltage Verase is applied to the substrate 111.

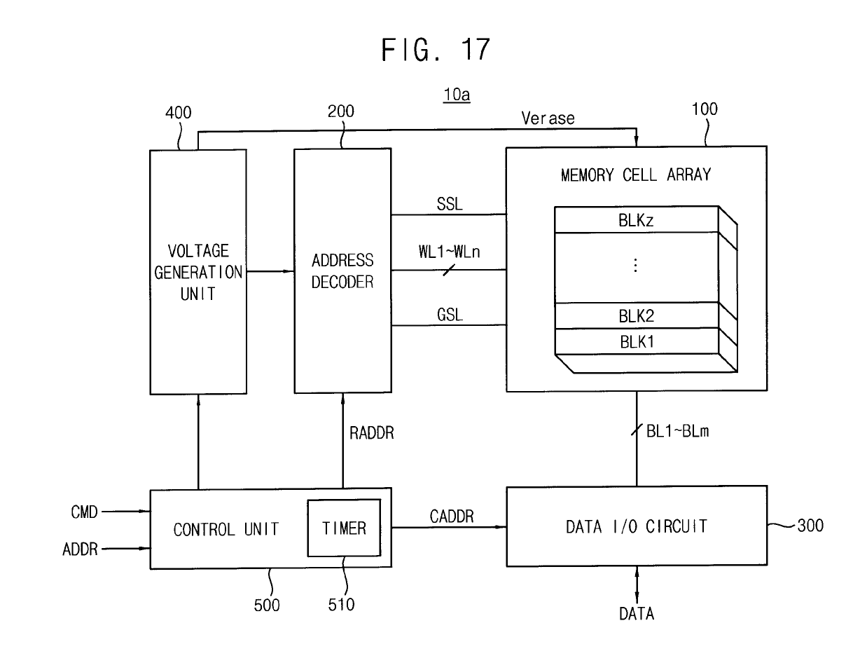

FIG. 17 is a block diagram illustrating the nonvolatile memory device of FIG. 1 according to an exemplary embodiment of the present inventive concept.

A nonvolatile memory device 10a of FIG. 17 is the same as the nonvolatile memory device 10 of FIG. 1 except that the control unit of the nonvolatile memory device 10a includes a timer 510.

Referring to FIGS. 13 to 17, the control unit 500 may control the voltage generation unit 400 to apply the erase voltage Verase to the substrate 111, and the timer 510 may determine whether the reference time elapses from the time at which the erase voltage Verase is applied to the substrate 111. When the reference time has elapsed from the time at which the erase voltage Verase is applied to the substrate 111, the control unit 500 may deactivate the first through k-th pass signals PS1˜PSk, which are provided to the gate electrodes of the first through k-th pass transistors PT1˜PTk, to turn off the first through k-th pass transistors PT1˜PTk. Therefore, the first through k-th word lines WL1˜WLk may be floated when the reference time elapses from the time at which the erase voltage Verase is applied to the substrate 111.

In some exemplary embodiments, the timer 510 may determine whether each of first through k-th reference times elapses from the time at which the erase voltage Verase is applied to the substrate 111. Among the first through k-th reference times, i-th reference time may be smaller than j-th reference time, where i and j are positive integers equal to or smaller than k and j is greater than i. When the first through k-th reference times elapse from the time at which the erase voltage Verase is applied to the substrate 111, the control unit 500 may deactivate the first through k-th pass signals PS1˜PSk, which are provided to the gate electrodes of the first through k-th pass transistors PT1˜PTk, respectively, to turn off the first through k-th pass transistors PT1˜PTk one by one. Therefore, the first through k-th word lines WL1˜WLk may be floated one by one in an order from the first word line WL1 to the k-th word line WLk when the first through k-th reference times elapse, respectively, from the time at which the erase voltage Verase is applied to the substrate 111.

In some exemplary embodiments, the first through k-th word lines WL1˜WLk, which are formed adjacent to the substrate 111, among the first through n-th word lines WL1˜WLn may be floated when a voltage of the substrate 111 reaches a reference voltage.

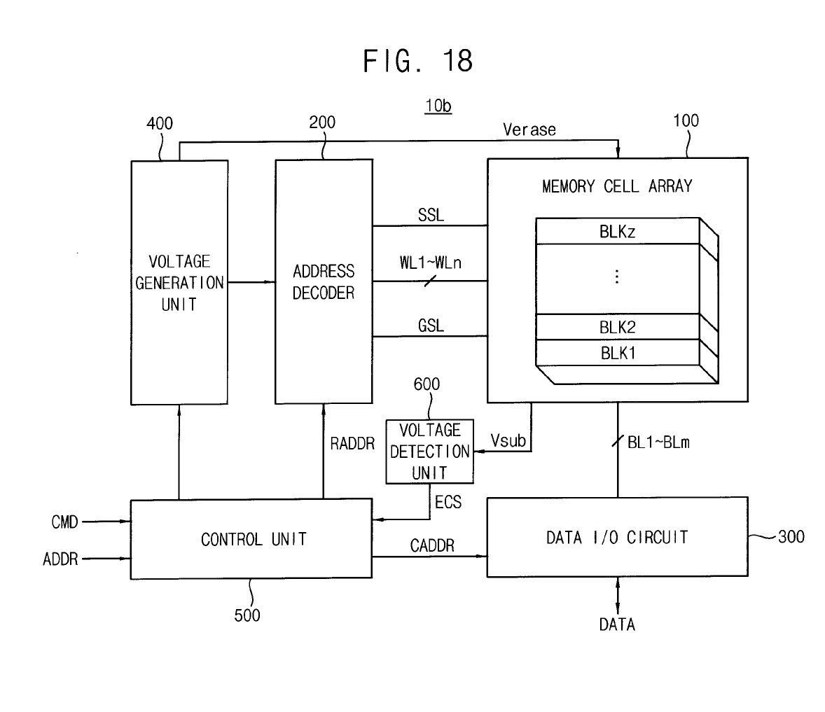

FIG. 18 is a block diagram illustrating another example of the nonvolatile memory device of FIG. 1.

A nonvolatile memory device 10b of FIG. 18 is the same as the nonvolatile memory device 10 of FIG. 1 except that the nonvolatile memory device 10b further includes a voltage detection unit 600.

Referring to FIGS. 13 to 16 and 18, the control unit 500 may control the voltage generation unit 400 to apply the erase voltage Verase to the substrate 111, and the voltage detection unit 600 may detect the voltage Vsub of the substrate 111 to determine whether the voltage Vsub of the substrate 111 reaches the reference voltage. When the voltage Vsub of the substrate 111 reaches the reference voltage, the voltage detection unit 600 may generate an erase control signal ECS. The control unit 500 may deactivate the first through k-th pass signals PS1˜PSk, which are provided to the gate electrodes of the first through k-th pass transistors PT1˜PTk, to turn off the first through k-th pass transistors PT1˜PTk in response to the erase control signal ECS. Therefore, the first through k-th word lines WL1˜WLk may be floated when the voltage Vsub of the substrate 111 reaches the reference voltage.

In some exemplary embodiments, the voltage detection unit 600 may detect the voltage Vsub of the substrate 111 to determine whether the voltage Vsub of the substrate 111 reaches each of first through k-th reference voltages. Among the first through k-th reference voltages, i-th reference voltage may be smaller than j-th reference voltage, where i and j are positive integers equal to or smaller than k and j is greater than i. When the voltage Vsub of the substrate 111 reaches the first through k-th reference voltages, the voltage detection unit 600 may generate first through k-th erase control signals, respectively. The control unit 500 may deactivate the first through k-th pass signals PS1˜PSk, which are provided to the gate electrodes of the first through k-th pass transistors PT1˜PTk, to turn off the first through k-th pass transistors PT1˜PTk one by one in response to the first through k-th erase control signals, respectively. Therefore, the first through k-th word lines WL1˜WLk may be floated one by one in an order from the first word line WL1 to the k-th word line WLk when the voltage Vsub of the substrate 111 reaches the first through k-th reference voltages, respectively.

As described above with references to FIGS. 1 to 18, the plurality of pillars PL11, PL12, PL21, PL22 may be a V-shaped cylinder having a diameter reducing as it gets closer to the bottom portion. Since voltage differences between the channel layer 114 and the gate electrode layers of the memory cells MC1˜MCk are smaller than voltage differences between the channel layer 114 and the gate electrode layers of the memory cells MC(k+1)˜MCn during the erase operation, differences between the erase speeds of the memory cells MC1˜MCn according to the heights from the substrate 111 may be reduced. As such, the method of erasing the nonvolatile memory device 10 according to exemplary embodiments may effectively reduce the threshold voltage distribution of the memory cells MC1˜MCn in the erased state after the erase operation is performed on the memory cells MC1˜MCn.

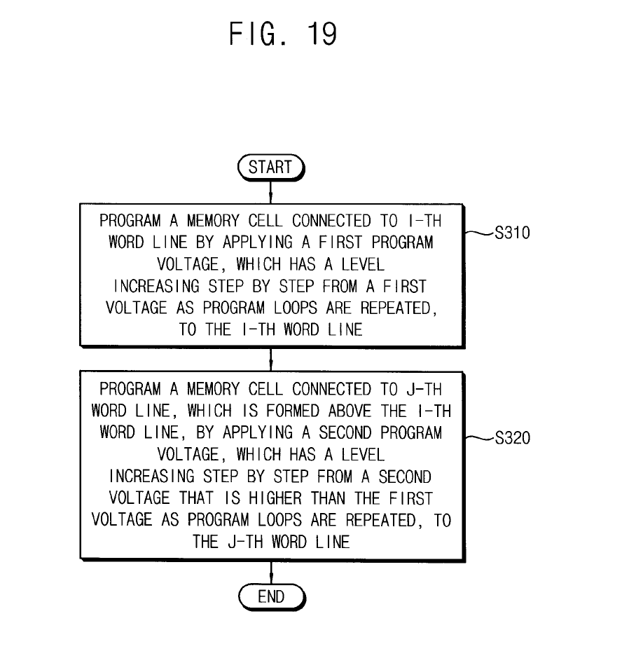

FIG. 19 is a flow chart illustrating a method of programming a nonvolatile memory device according to exemplary embodiments.

A nonvolatile memory device performing the method of programming of FIG. 19 includes a substrate and first through n-th word lines stacked in a direction perpendicular to the substrate. Here, the first word line corresponds to a lowermost word line among the first through n-th word lines, and the n-th word line corresponds to an uppermost word line among the first through n-th word lines. Here, n represents an integer equal to or greater than two.

For example, the method of programming of FIG. 19 may be performed by the nonvolatile memory device 10 of FIG. 1.

Hereinafter, the method of programming the nonvolatile memory device 10 will be described with reference to FIGS. 1 to 7 and 19.

Referring to FIG. 19, a target memory cell connected to i-th word line WLi is programmed (step S310) by applying a first program voltage, which has a level increasing in steps from a first voltage as program loops are repeated, to the i-th word line WLi, and a target memory cell connected to j-th word line WLj, which is formed above the i-th word line WLi, is programmed (step S320) by applying a second program voltage, which has a level increasing in steps from a second voltage that is higher than the first voltage as program loops are repeated, to the j-th word line WLj, where, i and j are positive integers equal to or smaller than n and j is greater than i.

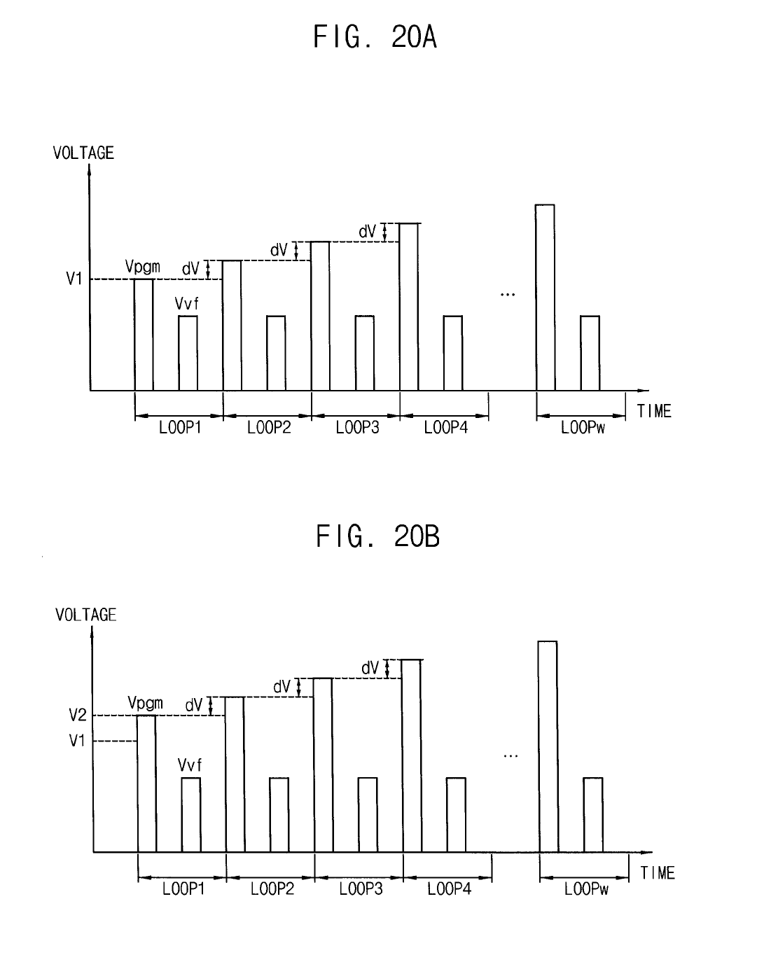

FIGS. 20A and 20B are graphs for describing the method of programming the nonvolatile memory device of FIG. 19 according to an exemplary embodiment of the present inventive concept.

The method of programming the target memory cell connected to the i-th word line WLi will be described with reference to FIG. 20A, and the method of programming the target memory cell connected to the j-th word line WLj, which is formed above the i-th word line WLi, will be described with reference to FIG. 20B.

Referring to FIG. 20A, when the target memory cell is connected to the i-th word line WLi, a program voltage Vpgm having a level of a first voltage V1 may be applied to the i-th word line WLi and a pass voltage lower than the program voltage Vpgm may be applied to the first through n-th word lines WL1˜WLn except for the i-th word line WLi in a first program loop LOOP1. In some exemplary embodiments, the program voltage Vpgm and the pass voltage may be provided from the voltage generation unit 400. For example, the voltage generation unit 400 may generate the program voltage Vpgm and the pass voltage and provide the program voltage Vpgm and the pass voltage to the address decoder 200, and the address decoder 200 may apply the program voltage Vpgm to the i-th word line WLi and apply the pass voltage to the first through n-th word lines WL1˜WLn except for the i-th word line WLi under a control of the control unit 500.

In the first program loop LOOP1, a program permission voltage may be applied to a bit line connected to the target memory cell among the plurality of bit lines BL1˜BLm, and a program inhibition voltage may be applied to the plurality of bit lines BL1˜BLm except for the bit line connected to the target memory cell. For example, the program permission voltage may be the ground voltage GND, and the program inhibition voltage may be a supply voltage. During the program operation, the supply voltage may be applied to the string selection line SSL, and the ground voltage GND may be applied to the substrate 111.

Therefore, a strong electric field may be formed between the gate electrode layer and the channel layer 114 of the target memory cell such that the program operation may be performed on the target memory cell.

After that, whether the target memory cell connected to the i-th word line WLi is in a programmed state may be determined by applying a verification voltage Vvf to the i-th word line WLi to compare the threshold voltage of the target memory cell with the verification voltage Vvf.

When the target memory cell is in a program failed state, the program loops may be repeated until the target memory cell is in a programmed state. The program operation, in which the program voltage Vpgm is applied to the i-th word line WLi, and the verification operation, in which the verification voltage Vvf is applied to the i-th word line WLi, may be performed alternately in each of the program loops LOOP1, LOOP2, LOOP3, LOOP4, . . . , LOOPw. Here, w represents a positive integer. A magnitude of the verification voltage Vvf applied to the i-th word line WLi in each of the program loops LOOP1, LOOP2, LOOP3, . . . , LOOP4, LOOPw may be constant.

When the target memory cell is in a programmed state, the program loops may be terminated such that no more program operation may be performed on the target memory cell.

As illustrated in FIG. 20A, a level of the program voltage Vpgm applied to the i-th word line WLi may increase in steps from the first voltage V1 by a unit of a step level dV as program loops are repeated. For example, the level of the program voltage Vpgm in the first program loop LOOP1 may be the first voltage V1, the level of the program voltage Vpgm in the second program loop LOOP2 may be greater than the first voltage V1 by the step level dV, and the level of the program voltage Vpgm in the third program loop LOOP3 may be greater than the first voltage V1 by two times of the step level dV.

Referring to FIG. 20B, when the target memory cell is connected to the j-th word line WLi, which is formed above the i-th word line WLi, the program voltage Vpgm having a level of a second voltage V2 higher than the first voltage V1 may be applied to the j-th word line WLj and the pass voltage lower than the program voltage Vpgm may be applied to the first through n-th word lines WL1˜WLn except for the j-th word line WLj in a first program loop LOOP1.

In the first program loop LOOP1, the program permission voltage may be applied to a bit line connected to the target memory cell among the plurality of bit lines BL1˜BLm, and the program inhibition voltage may be applied to the plurality of bit lines BL1˜BLm except for the bit line connected to the target memory cell. For example, the program permission voltage may be the ground voltage GND, and the program inhibition voltage may be the supply voltage. During the program operation, the supply voltage may be applied to the string selection line SSL, and the ground voltage GND may be applied to the substrate 111.

Therefore, a strong electric field may be formed between the gate electrode layer and the channel layer 114 of the target memory cell such that the program operation may be performed on the target memory cell.

After that, whether the target memory cell connected to the j-th word line WLj is in a programmed state may be determined by applying the verification voltage Vvf to the j-th word line WLj to compare the threshold voltage of the target memory cell with the verification voltage Vvf.

When the target memory cell is in the program failed state, the program loops may be repeated until the target memory cell is in a programmed state. The program operation, in which the program voltage Vpgm is applied to the j-th word line WLj, and the verification operation, in which the verification voltage Vvf is applied to the j-th word line WLj, may be performed alternately in each of the program loops LOOP1, LOOP2, LOOP3, LOOP4, . . . , LOOPw. Here, w represents a positive integer. A magnitude of the verification voltage Vvf applied to the j-th word line WLj in each of the program loops LOOP1, LOOP2, LOOP3, LOOP4, . . . , LOOPw may be constant.

When the target memory cell is in the programmed state, the program loops may be terminated such that no more program operation may be performed on the target memory cell.

As illustrated in FIG. 20B, the level of the program voltage Vpgm applied to the j-th word line WLj may increase in steps from the second voltage V2 by a unit of the step level dV as program loops are repeated. For example, the level of the program voltage Vpgm in the first program loop LOOP1 may be the second voltage V2 higher than the first voltage V1, the level of the program voltage Vpgm in the second program loop LOOP2 may be greater than the second voltage V2 by the step level dV, and the level of the program voltage Vpgm in the third program loop LOOP3 may be greater than the second voltage V2 by two times of the step level dV.

In some exemplary embodiments, a stepwise increment, which is the step level dV, of the program voltage Vpgm applied to the i-th word line WLi in each of the program loops LOOP1, LOOP2, LOOP3, LOOP4, . . . , LOOPw while programming the target memory cell connected to the i-th word line WLi may be substantially the same as a stepwise increment, which is the step level dV, of the program voltage Vpgm applied to the j-th word line WLj in each of the program loops LOOP1, LOOP2, LOOP3, LOOP4, . . . , LOOPw while programming the target memory cell connected to the j-th word line WLj. For example, the stepwise increment of the program voltage Vpgm used for programming a memory cell connected to each of the first through n-th word lines WL1˜WLn may be the same.

In some exemplary embodiments, a magnitude of the verification voltage Vvf applied to the i-th word line WLi in each of the program loops LOOP1, LOOP2, LOOP3, LOOP4, . . . , LOOPw while programming the target memory cell connected to the i-th word line WLi may be substantially the same as a magnitude of the verification voltage Vvf applied to the j-th word line WLj in each of the program loops LOOP1, LOOP2, LOOP3, LOOP4, . . . , LOOPw while programming the target memory cell connected to the j-th word line WLj. For example, the magnitude of the verification voltage Vvf used for programming a memory cell connected to each of the first through n-th word lines WL1˜WLn may be the same.

In some exemplary embodiments, the level of the program voltage Vpgm applied to a word line connected to the target memory cell in the first program loop LOOP1 may be relatively low when a height of the word line is relatively small, and the level of the program voltage Vpgm applied to a word line connected to the target memory cell in the first program loop LOOP1 may be relatively high when a height of the word line is relatively large. That is, as a height of the word line connected to the target memory cell is smaller, the level of the program voltage Vpgm applied to the word line may increase in steps from a lower voltage by a unit of the step level dV as program loops are repeated.

As described above with reference to FIGS. 1 to 7, the plurality of pillars PL11, PL12, PL21, PL22 may be a V-shaped cylinder having a diameter reducing as it gets closer to the bottom portion. Therefore, when the level of the program voltage Vpgm applied to each of the first through n-th word lines WL1˜WLn increases in steps from a same voltage by a unit of the step level dV as program loops are repeated while programming the target memory cell connected to each of the first through n-th word lines WL1˜WLn, a program speed of the target memory cell formed at a relatively lower portion among the memory cells MC1˜MCn may be greater than a program speed of the target memory cell formed at a relatively higher portion among the memory cells MC1˜MCn.

However, as described above, in the method of programming the nonvolatile memory device 10, as the height of the word line connected to the target memory cell is smaller, the level of the program voltage Vpgm applied to the word line may increase in steps from a lower voltage by a unit of the step level dV as program loops are repeated. Alternatively, as the height of the word line connected to the target memory cell is larger, the level of the program voltage Vpgm applied to the word line may increase in steps from a higher voltage by a unit of the step level dV as program loops are repeated. Therefore, the program speed of the target memory cell formed at a relatively higher portion among the memory cells MC1˜MCn may be increased to the program speed of the target memory cell formed at a relatively lower portion among the memory cells MC1˜MCn, such that overall program speed of the nonvolatile memory device 10 may be increased.

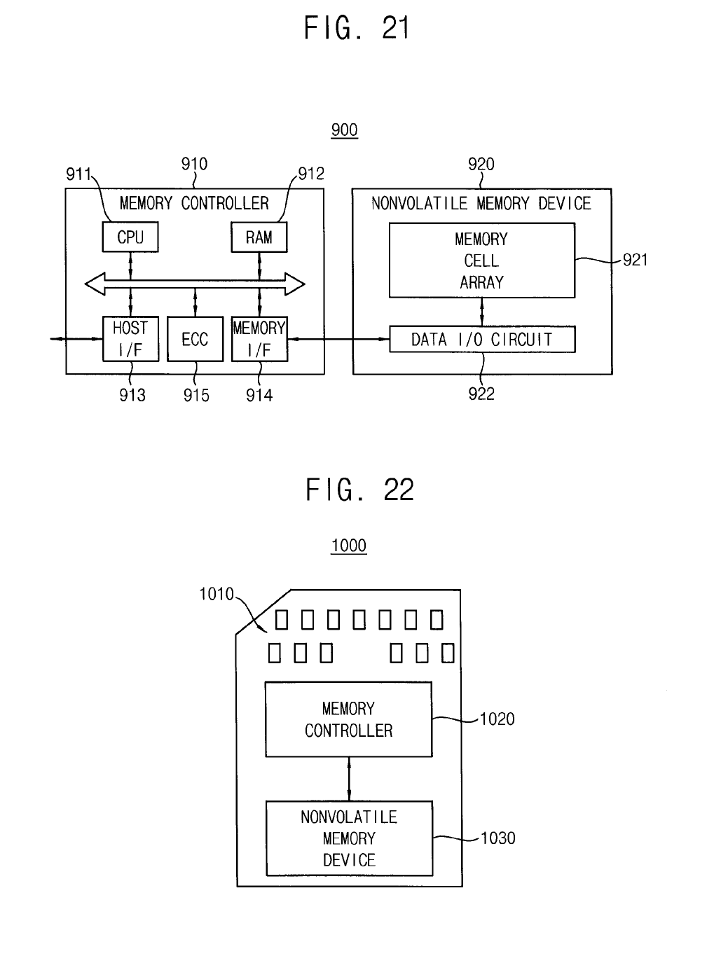

FIG. 21 is a block diagram illustrating a memory system according to exemplary embodiments.

Referring to FIG. 21, a memory system 900 includes a memory controller 910 and a nonvolatile memory device 920.

The nonvolatile memory device 920 includes a memory cell array 921 and a data I/O circuit 922.

The memory cell array 921 is formed on a substrate in a three-dimensional structure. For example, memory cells included in the memory cell array 921 may be formed in a direction perpendicular to the substrate. The memory cells included in the memory cell array 921 may be connected to a plurality of word lines, which are stacked in a direction perpendicular to the substrate, and a plurality of bit lines, which are formed in a direction parallel to the substrate.

The data I/O circuit 922 is connected to the memory cell array 921 through the plurality of bit lines. The data I/O circuit 922 may select at least one of the plurality of bit lines, output data read from a memory cell connected to the selected at least one bit line to the memory controller 910, and write data received from the memory controller 910 in a memory cell connected to the selected at least one bit line.

During an erase operation, the nonvolatile memory device 920 may apply a relatively low voltage to a word line formed at relatively large height and apply a relatively high voltage to a word line formed at relatively small height to reduce differences between erase speeds of the memory cells according to the heights from the substrate. Therefore, the nonvolatile memory device 920 may effectively reduce the threshold voltage distribution of the memory cells in an erased state after the erase operation is performed on the memory cells.

During a program operation, the nonvolatile memory device 920 may apply a program voltage, which has a level increasing in steps from a relatively low voltage by a unit of a step level as program loops are repeated, to a word line connected to a target memory cell when a height of the word line is relatively small, and apply a program voltage, which has a level increasing in steps from a relatively high voltage by a unit of the step level as program loops are repeated, to a word line connected to a target memory cell when a height of the word line is relatively large. Therefore, a program speed of the target memory cell formed at a relatively higher portion among the memory cells may be increased to a program speed of the target memory cell formed at a relatively lower portion among the memory cells, such that overall program speed of the nonvolatile memory device 920 may be increased.

The nonvolatile memory device 920 of FIG. 21 may be implemented with the nonvolatile memory device 10 of FIG. 1. The structure and operation of the nonvolatile memory device 10 of FIG. 1 are described above with reference to FIGS. 1 to 20B. Therefore, a detail description of the nonvolatile memory device 920 of FIG. 21 will be omitted here.

The memory controller 910 may control the nonvolatile memory device 920. The memory controller 910 may control data transfer between an external host and the nonvolatile memory device 920.

The memory controller 910 may include a central processing unit 911, a buffer memory 912, a host interface 913 and a memory interface 914.

The central processing unit 911 may perform operations for the data transfer. The buffer memory 912 may be implemented by a dynamic random access memory (DRAM), a static random access memory (SRAM), a phase change random access memory (PRAM), a ferroelectric random access memory (FRAM), a resistance random access memory (RRAM), a magnetic random access memory (MRAM), etc.

The buffer memory 912 may be an operational memory of the central processing unit 911. In some exemplary embodiments, the buffer memory 912 may be included in the memory controller 910. In other exemplary embodiments, the buffer memory 912 may be outside of the memory controller 910.

The host interface 913 may be coupled to the host, and the memory interface 914 may be coupled to the nonvolatile memory device 920. The central processing unit 911 may communicate with the host via the host interface 913. For example, the host interface 913 may be configured to communicate with the host using at least one of various interface protocols, such as a universal serial bus (USB), a multimedia card (MMC), a peripheral component interconnect-express (PCI-E), a small computer system interface (SCSI), a serial-attached SCSI (SAS), a serial advanced technology attachment (SATA), a parallel advanced technology attachment (PATA), an enhanced small disk interface (ESDI), integrated drive electronics (IDE), and so on.

Further, the central processing unit 911 may communicate with the nonvolatile memory device 920 via the memory interface 914.

In some exemplary embodiments, the memory controller 910 may further include an error correction block 915 for error correction.

In some exemplary embodiments, the memory controller 910 may be built in the nonvolatile memory device 920, or the memory controller 910 and the nonvolatile memory device 920 may be implemented as separate chips.

The memory system 900 may be implemented as a memory card, a solid state drive, and so on.

FIG. 22 is a block diagram illustrating a memory card according to exemplary embodiments.

Referring to FIG. 22, a memory card 1000 includes a plurality of connecting pins 1010, a memory controller 1020 and a nonvolatile memory device 1030.

The connecting pins 1010 may be coupled to an external host to transfer signals between the host and the memory card 1000. The connecting pins 1010 may include a clock pin, a command pin, a data pin and/or a reset pin.

The memory controller 1020 may receive data from the host, and may store the received data in the nonvolatile memory device 1030.

The nonvolatile memory device 1030 may include a memory cell array formed on a substrate in a three-dimensional structure. Memory cells included in the memory cell array may be formed in a direction perpendicular to the substrate. The memory cells included in the memory cell array may be connected to a plurality of word lines, which are stacked in a direction perpendicular to the substrate, and a plurality of bit lines, which are formed in a direction parallel to the substrate.

During an erase operation, the nonvolatile memory device 1030 may apply a relatively low voltage to a word line formed at relatively large height and apply a relatively high voltage to a word line formed at relatively small height to reduce differences between erase speeds of the memory cells according to the heights from the substrate. Therefore, the nonvolatile memory device 1030 may effectively reduce the threshold voltage distribution of the memory cells in an erased state after the erase operation is performed on the memory cells.

During a program operation, the nonvolatile memory device 1030 may apply a program voltage, which has a level increasing in steps from a relatively low voltage by a unit of a step level as program loops are repeated, to a word line connected to a target memory cell when a height of the word line is relatively small, and apply a program voltage, which has a level increasing in steps from a relatively high voltage by a unit of the step level as program loops are repeated, to a word line connected to a target memory cell when a height of the word line is relatively large. Therefore, a program speed of the target memory cell formed at a relatively higher portion among the memory cells may be increased to a program speed of the target memory cell formed at a relatively lower portion among the memory cells, such that overall program speed of the nonvolatile memory device 1030 may be increased.

The nonvolatile memory device 1030 of FIG. 22 may be implemented with the nonvolatile memory device 10 of FIG. 1. The structure and operation of the nonvolatile memory device 10 of FIG. 1 are described above with reference to FIGS. 1 to 20B. Therefore, a detail description of the nonvolatile memory device 1030 of FIG. 22 will be omitted here.

The memory card 1000 may include a MMC, an embedded MMC (eMMC), a hybrid embedded MMC (hybrid eMMC), a secure digital (SD) card, a micro-SD card, a memory stick, an ID card, a personal computer memory card international association (PCMCIA) card, a chip card, a USB card, a smart card, a compact flash (CF) card, and so on.

In some exemplary embodiments, the memory card 1000 may be coupled to the host, such as a desktop computer, a laptop computer, a tablet computer, a mobile phone, a smart phone, a music player, a personal digital assistants (PDA), a portable multimedia player (PMP), a digital television, a digital camera, a portable game console, and so on.

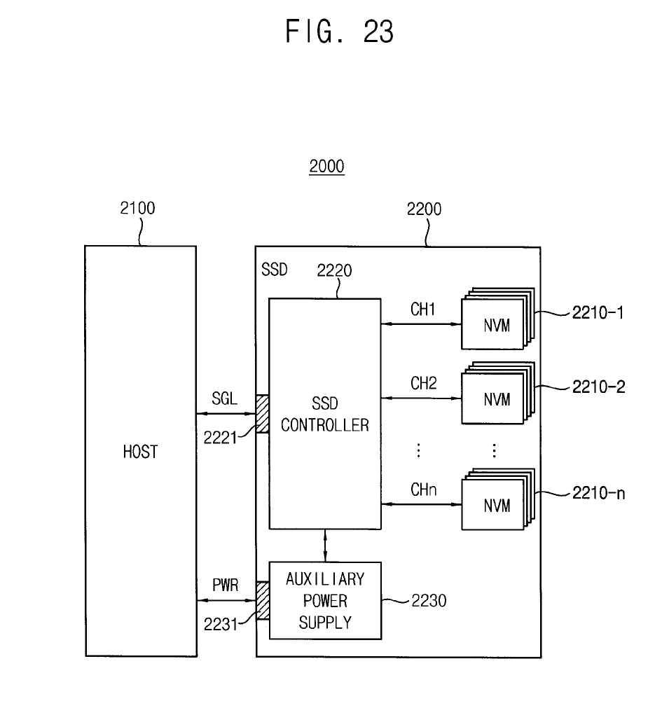

FIG. 23 is a block diagram illustrating a solid state drive (SSD) system according to exemplary embodiments.

Referring to FIG. 23, a SSD system 2000 includes a host 2100 and a SSD 2200.

The SSD 2200 includes first through n-th nonvolatile memory devices 2210-1, 2210-2, . . . , 2210-n and a SSD controller 2220. Here, n represents an integer greater than or equal to two.

The first through n-th nonvolatile memory devices 2210-1, 2210-2, . . . , 2210-n may be used as a storage medium of the SSD 2200.

Each of the first through n-th nonvolatile memory devices 2210-1, 2210-2, . . . , 2210-n may include a memory cell array formed on a substrate in a three-dimensional structure. Memory cells included in the memory cell array may be formed in a direction perpendicular to the substrate. The memory cells included in the memory cell array may be connected to a plurality of word lines, which are stacked in a direction perpendicular to the substrate, and a plurality of bit lines, which are formed in a direction parallel to the substrate.

During an erase operation, each of the first through n-th nonvolatile memory devices 2210-1, 2210-2, . . . , 2210-n may apply a relatively low voltage to a word line formed at relatively large height and apply a relatively high voltage to a word line formed at relatively small height to reduce differences between erase speeds of the memory cells according to the heights from the substrate. Therefore, each of the first through n-th nonvolatile memory devices 2210-1, 2210-2, . . . , 2210-n may effectively reduce the threshold voltage distribution of the memory cells in an erased state after the erase operation is performed on the memory cells.

During a program operation, each of the first through n-th nonvolatile memory devices 2210-1, 2210-2, . . . , 2210-n may apply a program voltage, which has a level increasing in steps from a relatively low voltage by a unit of a step level as program loops are repeated, to a word line connected to a target memory cell when a height of the word line is relatively small, and apply a program voltage, which has a level increasing in steps from a relatively high voltage by a unit of the step level as program loops are repeated, to a word line connected to a target memory cell when a height of the word line is relatively large. Therefore, a program speed of the target memory cell formed at a relatively higher portion among the memory cells may be increased to a program speed of the target memory cell formed at a relatively lower portion among the memory cells, such that overall program speed of each of the first through n-th nonvolatile memory devices 2210-1, 2210-2, . . . , 2210-n may be increased.

Each of the first through n-th nonvolatile memory devices 2210-1, 2210-2, . . . , 2210-n of FIG. 23 may be implemented with the nonvolatile memory device 10 of FIG. 1. The structure and operation of the nonvolatile memory device 10 of FIG. 1 are described above with reference to FIGS. 1 to 20B. Therefore, a detail description of each of the first through n-th nonvolatile memory devices 2210-1, 2210-2, . . . 2210-n of FIG. 23 will be omitted here.

The SSD controller 2220 is coupled to the first through n-th nonvolatile memory devices 2210-1, 2210-2, . . . , 2210-n by first through n-th channels CH1, CH2, . . . , CHn, respectively.

The SSD controller 2220 may exchange a signal SGL with the host 2100 through a signal connector 2221. The signal SGL may include a command, an address and data. The SSD controller 2220 may perform a program operation and a read operation on the first through n-th nonvolatile memory devices 2210-1, 2210-2, . . . , 2210-n according to the command received from the host 2100.

The SSD 2200 may further include an auxiliary power supply 2230. The auxiliary power supply 2230 may receive power PWR from the host 2100 through a power connector 2231 and provide power to the SSD controller 2220. The auxiliary power supply 2230 may be placed inside or outside the SSD 2200. For example, the auxiliary power supply 2230 may be placed in a main board and provide auxiliary power to the SSD 2200.

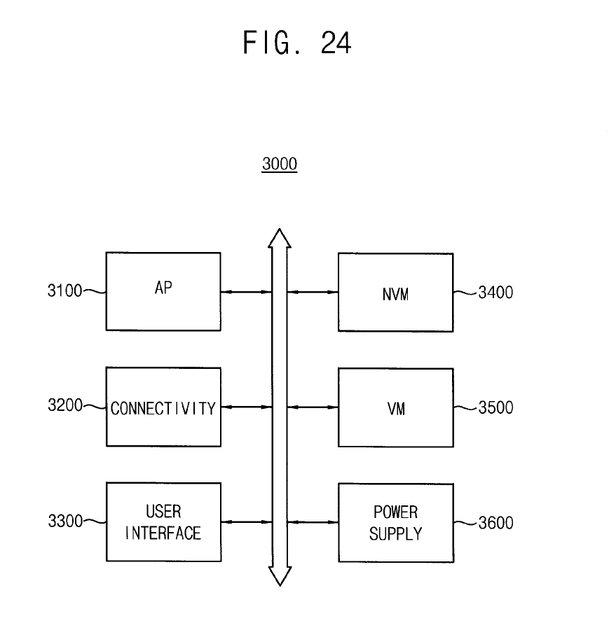

FIG. 24 is a block diagram illustrating a mobile system according to exemplary embodiments.

Referring to FIG. 24, a mobile system 3000 includes an application processor AP 3100, a connectivity unit 3200, a user interface 3300, a nonvolatile memory device NVM 3400, a volatile memory device VM 3500 and a power supply 3600.

In some embodiments, the mobile system 3000 may be a mobile phone, a smart phone, a personal digital assistant (PDA), a portable multimedia player (PMP), a digital camera, a music player, a portable game console, a navigation system, etc.

The application processor 3100 may execute applications, such as a web browser, a game application, a video player, etc. In some exemplary embodiments, the application processor 3100 may include a single core or multiple cores. For example, the application processor 3100 may be a multi-core processor, such as a dual-core processor, a quad-core processor, a hexa-core processor, etc. The application processor 3100 may include an internal or external cache memory.

The connectivity unit 3200 may perform wired or wireless communication with an external device. For example, the connectivity unit 3200 may perform Ethernet communication, near field communication (NFC), radio frequency identification (RFID) communication, mobile telecommunication, memory card communication, universal serial bus (USB) communication, etc. In some embodiments, the connectivity unit 3200 may include a baseband chipset that supports communications, such as global system for mobile communications (GSM), general packet radio service (GPRS), wideband code division multiple access (WCDMA), high speed downlink uplink packet access (HSxPA), etc.

The nonvolatile memory device 3400 may store a boot image for booting the mobile system 3000.

The nonvolatile memory device 3400 may include a memory cell array formed on a substrate in a three-dimensional structure. Memory cells included in the memory cell array may be formed in a direction perpendicular to the substrate. The memory cells included in the memory cell array may be connected to a plurality of word lines, which are stacked in a direction perpendicular to the substrate, and a plurality of bit lines, which are formed in a direction parallel to the substrate.

During an erase operation, the nonvolatile memory device 3400 may apply a relatively low voltage to a word line formed at relatively large height and apply a relatively high voltage to a word line formed at relatively small height to reduce differences between erase speeds of the memory cells according to the heights from the substrate. Therefore, the nonvolatile memory device 3400 may effectively reduce the threshold voltage distribution of the memory cells in an erased state after the erase operation is performed on the memory cells.

During a program operation, the nonvolatile memory device 3400 may apply a program voltage, which has a level increasing in steps from a relatively low voltage by a unit of a step level as program loops are repeated, to a word line connected to a target memory cell when a height of the word line is relatively small, and apply a program voltage, which has a level increasing in steps from a relatively high voltage by a unit of the step level as program loops are repeated, to a word line connected to a target memory cell when a height of the word line is relatively large. Therefore, a program speed of the target memory cell formed at a relatively higher portion among the memory cells may be increased to a program speed of the target memory cell formed at a relatively lower portion among the memory cells, such that overall program speed of the nonvolatile memory device 3400 may be increased.

The nonvolatile memory device 3400 of FIG. 24 may be implemented with the nonvolatile memory device 10 of FIG. 1. The structure and operation of the nonvolatile memory device 10 of FIG. 1 are described above with reference to FIGS. 1 to 20B. Therefore, a detail description of the nonvolatile memory device 3400 of FIG. 24 will be omitted here.

The volatile memory device 3500 may store data processed by the application processor 3100, or may operate as a working memory.

The user interface 3300 may include at least one input device, such as a keypad, a touch screen, etc., and at least one output device, such as a speaker, a display device, etc.

The power supply 3600 may supply a power supply voltage to the mobile system 3000.

In some embodiments, the mobile system 3000 may further include an image processor, and/or a storage device, such as a memory card, a solid state drive (SSD), a hard disk drive (HDD), a CD-ROM, etc.

In some embodiments, the mobile system 3000 and/or components of the mobile system 3000 may be packaged in various forms, such as package on package (PoP), ball grid arrays (BGAs), chip scale packages (CSPs), plastic leaded chip carrier (PLCC), plastic dual in-line package (PDIP), die in waffle pack, die in wafer form, chip on board (COB), ceramic dual in-line package (CERDIP), plastic metric quad flat pack (MQFP), thin quad flat pack (TQFP), small outline IC (SOIC), shrink small outline package (SSOP), thin small outline package (TSOP), system in package (SIP), multi chip package (MCP), wafer-level fabricated package (WFP), or wafer-level processed stack package (WSP).

The foregoing is illustrative of the present inventive concept and is not to be construed as limiting thereof. Although a few exemplary embodiments have been described, those skilled in the art will readily appreciate that many modifications are possible in the exemplary embodiments without materially departing from the novel teachings and advantages of the present inventive concept. Accordingly, all such modifications are intended to be included within the scope of the present inventive concept as defined in the claims. Therefore, it is to be understood that the foregoing is illustrative of various exemplary embodiments and is not to be construed as limited to the specific exemplary embodiments disclosed, and that modifications to the disclosed exemplary embodiments, as well as other exemplary embodiments, are intended to be included within the scope of the appended claims.

What is claimed is:

1. A method of operating a nonvolatile memory device having a substrate and first through n-th word lines stacked in a direction perpendicular to the substrate, the method comprising:
applying first through k-th word line voltages to first through k-th word lines, respectively, which are formed adjacent to the substrate, among the first through n-th word lines, n being an integer equal to or greater than two, k being a positive integer smaller than n;
applying (k+1)-th through n-th word line voltages to (k+1)-th through n-th word lines, respectively, which are formed above the first through k-th word lines, among the first through n-th word lines, each of the (k+1)-th through n-th word line voltages being lower than each of the first through k-th word line voltages; and
applying an erase voltage, which is higher than the first through n-th word line voltages, to the substrate.

2. The method of claim 1, wherein the first through k-th word line voltages are positive voltages and the (k+1)-th through n-th word line voltages are ground voltages.

3. The method of claim 2, wherein i-th word line voltage is equal to or higher than j-th word line voltage, where i and j are positive integers equal to or smaller than k and j is greater than i.

4. The method of claim 1, wherein the first through k-th word line voltages are ground voltages and the (k+1)-th through n-th word line voltages are negative voltages.

5. The method of claim 1, wherein an i-th word line voltage is equal to or higher than a j-th word line voltage, where i and j are positive integers equal to or smaller than n, and j is greater than i.

6. The method of claim 1,
wherein the first through n-th word lines are connected to gate electrodes of first through n-th memory cells, respectively, and
wherein an m-th word line voltage is higher than a rest of the first through k-th word line voltages when an m-th memory cell has an a typical shape, where m is a positive integer equal to or smaller than k.

7. The method of claim 1, wherein the first through n-th word line voltages are provided from a voltage generation unit included in the nonvolatile memory device.

8. A method of operating a nonvolatile memory device having a substrate and first through n-th word lines stacked in a direction perpendicular to the substrate, the method comprising:
applying a ground voltage to the first through n-th word lines, n being an integer equal to or greater than two;
applying an erase voltage to the substrate; and
floating first through k-th word lines, which are formed adjacent to the substrate, among the first through n-th word lines, k being a positive integer equal to or smaller than n.

9. The method of claim 8, wherein floating the first through k-th word lines includes:
floating the first through k-th word lines when a reference time elapses from a time at which the erase voltage is applied to the substrate.

10. The method of claim 9,
wherein the nonvolatile memory device further includes a timer, and
wherein whether the reference time elapses from the time at which the erase voltage is applied to the substrate is determined using the timer.

11. The method of claim 8, wherein floating the first through k-th word lines includes floating the first through k-th word lines when a voltage of the substrate reaches a reference voltage.

12. The method of claim 11,
wherein the nonvolatile memory device further includes a voltage detection unit configured to detect the voltage of the substrate, and
wherein whether the voltage of the substrate reaches the reference voltage is determined using the voltage detection unit.

13. The method of claim 8, wherein floating the first through k-th word lines includes floating the first through k-th word lines one by one in an order from the first word line to the k-th word line after the erase voltage is applied to the substrate.

14. The method of claim 13,
wherein floating the first through k-th word lines one by one in an order from the first word line to the k-th word line after the erase voltage is applied to the substrate includes floating the first through k-th word lines when first through k-th reference times elapse, respectively, from a time at which the erase voltage is applied to the substrate, and
wherein an i-th reference time is smaller than a j-th reference time, where i and j are positive integers equal to or smaller than k and j is greater than i.

15. The method of claim 13,
wherein floating the first through k-th word lines one by one in an order from the first word line to the k-th word line after the erase voltage is applied to the substrate includes floating the first through k-th word lines when a voltage of the substrate reaches first through k-th reference voltages, respectively, and
wherein an i-th reference voltage is smaller than a j-th reference voltage, where i and j are positive integers equal to or smaller than k and j is greater than i.

16. The method of claim 8,
wherein applying the ground voltage to the first through n-th word lines includes:
applying the ground voltage to first through n-th pass transistors, which are coupled to the first through n-th word lines, respectively, and
turning on the first through n-th pass transistors, and
wherein floating the first through k-th word lines includes turning off first through k-th pass transistors, which are coupled to the first through k-th word lines, respectively, after the erase voltage is applied to the substrate.

17. The method of claim 16, wherein turning off the first through k-th pass transistors after the erase voltage is applied to the substrate includes turning off the first through k-th pass transistors one by one in an order from the first pass transistor to the k-th pass transistor after the erase voltage is applied to the substrate.

18. A method of operating a nonvolatile memory device having a substrate and first through n-th word lines stacked in a direction perpendicular to the substrate, the method comprising:
programming a target memory cell connected to an i-th word line by applying a first program voltage to the i-th word line, a level of the first program voltage increasing in steps from a first voltage as program loops are repeated, i being a positive integer equal to or smaller than n; and
programming a target memory cell connected to a j-th word line, which is formed above the i-th word line, by applying a second program voltage to the j-th word line, a level of the second program voltage increasing in steps from a second voltage, which is higher than the first voltage, as program loops are repeated, j being an integer greater than i and equal to or smaller than n.

19. The method of claim 18, wherein a stepwise increment of the first program voltage is substantially the same as a stepwise increment of the second program voltage.

20. The method of claim 18, further comprising:
verifying whether the target memory cell connected to the i-th word line is in a programmed state by applying a verification voltage having a constant magnitude to the i-th word line in each program loop while programming the target memory cell connected to the i-th word line; and
verifying whether the target memory cell connected to the j-th word line is in a programmed state by applying the verification voltage having the constant magnitude to the j-th word line in each program loop while programming the target memory cell connected to the j-th word line.
